(19) United States
(12) Patent Application Publication
(10) Pub. No.: US 2015/0305156 A1
(43) Pub. Date: Oct. 22, 2015

(54) SUSPENSION BOARD WITH CIRCUIT

(71) Applicant: NITTO DENKO CORPORATION, Osaka (JP)

(72) Inventors: Yoshito FUJIMURA, Osaka (JP); Naohiro TERADA, Osaka (JP)

(73) Assignee: NITTO DENKO CORPORATION, Osaka (JP)

(21) Appl. No.: 14/690,827

(22) Filed: Apr. 20, 2015

(30) Foreign Application Priority Data
Apr. 21, 2014 (JP) 2014-087607

(51) Int. Cl. H05K 1/11; H05K 1/18

(52) U.S. Cl. CPC H05K 1/113; H05K 1/18

(57) ABSTRACT

A suspension board with circuit includes a pad portion configured to be bonded to an electronic element. The pad portion includes a conductive layer; in the pad portion, a through hole passing through the pad portion with its periphery closed by the pad portion is formed; and at least a part of an inner peripheral surface facing the through hole in the pad portion is divided only by the conductive layer.

### CROSS-REFERENCE TO RELATED APPLICATION

The present application claims priority from Japanese Patent Application No. 2014-087607 filed on Apr. 21, 2014, the contents of which are hereby incorporated by reference into this application.

### BACKGROUND OF THE INVENTION

1. Field of the Invention

The present invention relates to a suspension board with circuit, to be specific, to a suspension board with circuit used in a hard disk drive.

2. Description of Related Art

It has been conventionally known that a magnetic head and a piezoelectric element are included in a gimbal portion of a suspension board with circuit and a position and an angle of the magnetic head are finely adjusted by moving the gimbal portion in a stretching and shrinking movement of the piezoelectric element. In such a suspension board with circuit, a terminal of a conductive pattern included in the suspension board with circuit is required to be connected to the piezoelectric element.

As such a connection structure, for example, the following connection structure has been proposed (ref: for example, Japanese Unexamined Patent Publication No. 2010-154632). In the structure, a through hole passing through a thickness direction is provided in a terminal member consisting of an electrically insulating layer and a wire portion; an electrically conductive adhesive fills the through hole; and an electrode of the piezoelectric element is electrically connected to the wire portion via the electrically conductive adhesive. In the terminal member described in Japanese Unexamined Patent Publication No. 2010-154632, an inner peripheral surface of the electrically insulating layer is formed to be flush with that of the wire portion.

### SUMMARY OF THE INVENTION

In recent years, an excellent bonding strength of the terminal with the electrode of the piezoelectric element and furthermore, excellent electrical connection reliability of the terminal with the electrode have been required.

In the terminal member described in Japanese Unexamined Patent Publication No. 2010-154632, however, the inner peripheral surface of the electrically insulating layer is formed to be flush with that of the wire portion, so that the bonding strength thereof with the electrically conductive adhesive filling the through hole is insufficient. Thus, in the terminal member described in Japanese Unexamined Patent Publication No. 2010-154632, the electrical connection reliability of the terminal with the piezoelectric element is insufficient, so that the above-described requirement cannot be satisfied.

It is an object of the present invention to provide a suspension board with circuit having an excellent bonding strength and excellent electrical connection reliability of a pad portion or a connecting portion with an electronic element.

A suspension board with circuit of the present invention includes a pad portion configured to be bonded to an electronic element, wherein the pad portion includes a conductive layer; in the pad portion, a through hole passing through the pad portion with its periphery closed by the pad portion is formed; and at least a part of an inner peripheral surface facing the through hole in the pad portion is divided only by the conductive layer.

According to the suspension board with circuit, when a bonding material is provided in the pad portion and the pad portion is bonded to the electronic element, the bonding material can fill the through hole and at least a part of the inner peripheral surface, facing the through hole in the pad portion, which is divided only by the conductive layer can be covered with the bonding material in an embedded state. Thus, the bonding strength of the electronic element with the pad portion can be improved. As a result, the electrical connection reliability of the electronic element with the conductive layer in the pad portion can be improved.

In the suspension board with circuit of the present invention, it is preferable that the pad portion further includes an insulating layer that is disposed at one surface in a penetrating direction of the through hole in the conductive layer and the part in the pad portion is disposed at the inner side of the through hole with respect to the inner peripheral surface facing the through hole in the insulating layer.

In the suspension board with circuit, the pad portion includes the insulating layer that is disposed at one surface in the penetrating direction of the through hole in the conductive layer. Thus, the insulating layer can reinforce the conductive layer in the pad portion.

Meanwhile, the part in the pad portion is disposed at the inner side of the through hole with respect to the inner peripheral surface facing the through hole in the insulating layer. That is, the part in the pad portion is disposed so as to protrude toward the inner side of the through hole with respect to the inner peripheral surface of the insulating layer, so that when a bonding material is provided in the pad portion and the pad portion is bonded to the electronic element, the part in the pad portion is embedded in the bonding material. Thus, the bonding strength of the electronic element with the pad portion can be further improved. As a result, the electrical connection reliability of the electronic element with the conductive layer in the pad portion can be further improved.

In the suspension board with circuit of the present invention, it is preferable that both surfaces in the penetrating direction of the through hole in the conductive layer that divides the part in the pad portion are exposed.

When a bonding material is provided in the pad portion of the suspension board with circuit and the pad portion is bonded to the electronic element, the bonding material can be easily and surely brought into contact with both surfaces in the penetrating direction of the conductive layer. Thus, the bonding strength of the electronic element with the pad portion can be further improved. As a result, the electrical connection reliability of the electronic element with the conductive layer in the pad portion can be further improved.

In the suspension board with circuit of the present invention, it is preferable that the entire inner peripheral surface in the pad portion is divided only by the conductive layer.

In the suspension board with circuit, the entire inner peripheral surface facing the through hole in the pad portion is divided only by the conductive layer, so that when a bonding material is provided in the pad portion and the pad portion is bonded to the electronic element, a contact area of the bonding material with the conductive layer that divides the inner peripheral surface facing the through hole in the pad portion can be sufficiently ensured. Thus, the electrical connection reliability of the electronic element with the conductive layer in the pad portion can be further improved.

A suspension board with circuit of the present invention includes an electronic element, a connecting portion electrically connecting to the electronic element, and a bonding material bonding the electronic element to the connecting portion, wherein the bonding material embeds the connecting portion.

In the suspension board with circuit, the bonding material embeds the connecting portion. Thus, the bonding material can improve the bonding strength of the electronic element with the connecting portion. As a result, the bonding material can improve the electrical connection reliability of the electronic element with the connecting portion.

In the suspension board with circuit of the present invention, it is preferable that the bonding material is provided so as to continuously surround one side in a thickness direction of the connecting portion, an opposite side in the thickness direction thereof, and a lateral side continuous to the one side and the opposite side in the thickness direction thereof.

In the suspension board with circuit, the bonding material is provided so as to continuously surround the one side in the thickness direction of the connecting portion, the opposite side in the thickness direction thereof, and the lateral side continuous to the one side and the opposite side in the thickness direction thereof. Thus, the bonding material can surely embed the connecting portion and further improve the bonding strength of the electronic element with the connecting portion.

In the suspension board with circuit of the present invention, it is preferable that an insulating layer and a conductive layer included at one side in a thickness direction of the insulating layer and including a terminal are included, wherein the connecting portion includes the insulating layer and the terminal and the bonding material is provided so as to continuously surround one side in the thickness direction of the insulating layer and the terminal in the connecting portion, an opposite side in the thickness direction thereof, and a lateral side continuous to the one side and the opposite side in the thickness direction thereof.

The suspension board with circuit includes the insulating layer and the conductive layer including the terminal. The connecting portion includes the insulating layer and the terminal. Thus, the insulating layer can reinforce the terminal in the connecting portion.

Additionally, the bonding material is provided so as to continuously surround the one side in the thickness direction of the insulating layer and the terminal in the connecting portion, the opposite side in the thickness direction thereof, and the lateral side continuous to the one side and the opposite side in the thickness direction thereof. Thus, the bonding material can further improve the bonding strength of the electronic element with the connecting portion.

In the suspension board with circuit of the present invention, it is preferable that a conductive layer including a terminal is included; the connecting portion includes the terminal; and the bonding material is provided so as to continuously surround one side in the thickness direction of the terminal in the connecting portion, an opposite side in the thickness direction thereof, and a lateral side continuous to the one side and the opposite side in the thickness direction thereof.

The suspension board with circuit includes the conductive layer including the terminal and the connecting portion includes the terminal, so that a contact area of the terminal with the bonding material can be increased, compared to a case where the terminal is supported by the insulating layer.

Additionally, the bonding material is provided so as to continuously surround the one side in the thickness direction of the terminal in the connecting portion, the opposite side in the thickness direction thereof, and the lateral side continuous to the one side and the opposite side in the thickness direction thereof. Thus, the bonding material can improve the electrical connection reliability of the electronic element with the connecting portion.

### BRIEF DESCRIPTION OF THE DRAWINGS

FIG. 1 shows a plan view of an assembly including a first embodiment of a suspension board with circuit of the present invention.

FIG. 2 shows a sectional view along an A-A line of the assembly shown in FIG. 1.

FIGS. 3A and 3B show enlarged plan views of a right-side connecting arm of the assembly shown in FIG. 1:

FIG. 3A illustrating a view in which a cover insulating layer is omitted and

FIG. 3B illustrating a view in which a cover insulating layer is illustrated.

FIGS. 4A to 4D show process drawings for illustrating a method for producing a suspension board with circuit:

FIG. 4A illustrating a step of preparing a metal supporting layer,

FIG. 4B illustrating a step of providing a base insulating layer,

FIG. 4C illustrating a step of providing a conductive layer, and

FIG. 4D illustrating a step of providing a cover insulating layer.

FIGS. 5E to 5G, subsequent to FIG. 4D, show process drawings for illustrating a method for producing a suspension board with circuit:

FIG. 5E illustrating a step of trimming a metal supporting layer,

FIG. 5F illustrating a step of partially removing a base insulating layer, and

FIG. 5G illustrating a step of providing a plating layer.

FIG. 6 shows a sectional view along a B-B line of a connecting arm shown in FIG. 1.

FIGS. 7A and 7B show a connecting arm of a second embodiment of a suspension board with circuit of the present invention:

FIG. 7A illustrating an enlarged plan view and

FIG. 7B illustrating a sectional view along a C-C line in FIG. 7A.

FIGS. 8A and 8B show enlarged plan views of a connecting arm of a third embodiment of a suspension board with circuit of the present invention:

FIG. 8A illustrating a view in which a cover insulating layer is omitted and

FIG. 8B illustrating a view in which a cover insulating layer is illustrated.

FIG. 9 shows a sectional view along a D-D line of the connecting arm shown in FIGS. 8A and 8B.

FIGS. 10A to 10D show process drawings for illustrating a method for producing the suspension board with circuit shown in FIG. 9:

FIG. 10A illustrating a step of preparing a metal supporting layer,

FIG. 10B illustrating a step of providing a base insulating layer,

FIG. 10C illustrating a step of providing a conductive layer, and

FIG. 10D illustrating a step of providing a cover insulating layer.

FIGS. 11E to 11G subsequent to FIG. 10D, show process drawings for illustrating a method for producing the suspension board with circuit shown in FIG. 9:

FIG. 11E illustrating a step of trimming a metal supporting layer,

FIG. 11F illustrating a step of removing a thin portion, and

FIG. 11G illustrating a step of providing a plating layer.

FIGS. 12A and 12B show enlarged plan views of a connecting arm of a fourth embodiment of a suspension board with circuit of the present invention:

FIG. 12A illustrating a view in which a cover insulating layer is omitted and

FIG. 12B illustrating a view in which a cover insulating layer is illustrated.

FIG. 13 shows a sectional view along an E-E line of the connecting arm shown in FIGS. 12A and 12B.

FIG. 14 shows a plan view of an assembly including a fifth embodiment of a suspension board with circuit of the present invention.

In FIG. 15, the right-side view shows an enlarged plan view of a gimbal portion of the assembly shown in FIG. 14 and the two left-side views show enlarged views of a connecting arm:

the upper left-side view illustrating a view in which a cover insulating layer is omitted and

the lower left-side view illustrating a view in which a cover insulating layer is illustrated.

FIG. 16 shows a sectional view along an F-F line of the gimbal portion shown in FIG. 15.

### DETAILED DESCRIPTION OF THE INVENTION

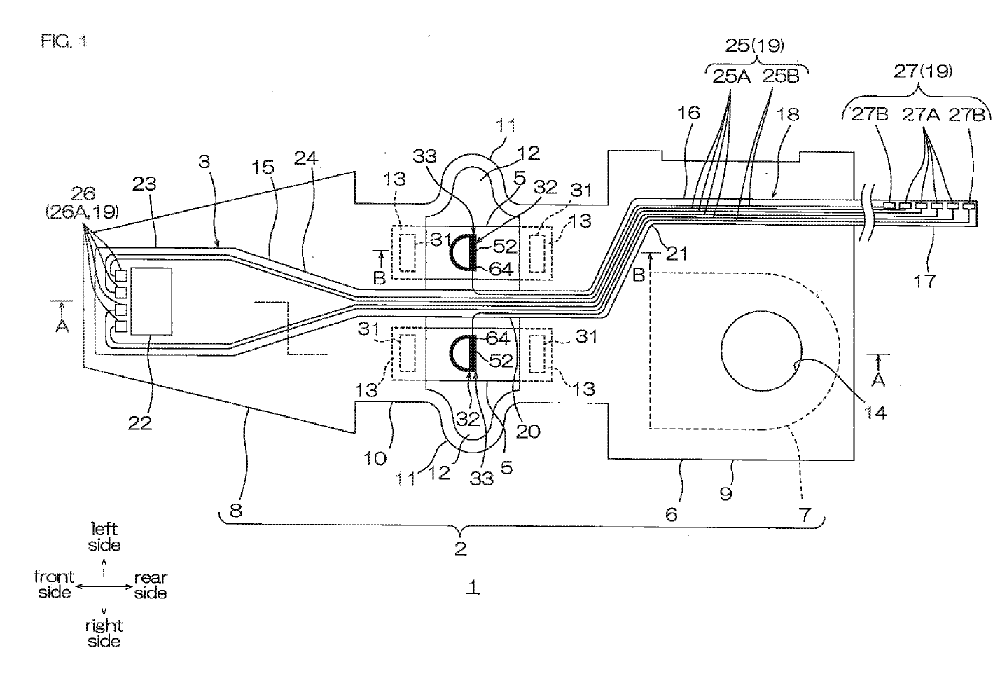

In FIG. 1, the right-left direction of the paper surface is referred to as a front-rear direction (a first direction); the left side of the paper surface is referred to as a front side (one side in the first direction); and the right side of the paper surface is referred to as a rear side (an opposite side in the first direction). In FIG. 1, the up-down direction of the paper surface is referred to as a right-left direction (a widthwise direction, a second direction orthogonal to the first direction); the upper side of the paper surface is referred to as a left side (one side in the widthwise direction, one side in the second direction); and the lower side of the paper surface is referred to as a right side (an opposite side in the widthwise direction, an opposite side in the second direction). In FIG. 1, the paper thickness direction of the paper surface is referred to as an up-down direction (a thickness direction, a penetrating direction of a through hole to be described later, a third direction orthogonal to the first and second directions); the near side of the paper surface is referred to as an upper side (one side in the thickness direction, one side in the penetrating direction, one side in the third direction); and the far side of the paper surface is referred to as a lower side (an opposite side in the thickness direction, an opposite side in the penetrating direction, an opposite side in the third direction). To be specific, directions are in conformity with direction arrows in each view.

### First Embodiment

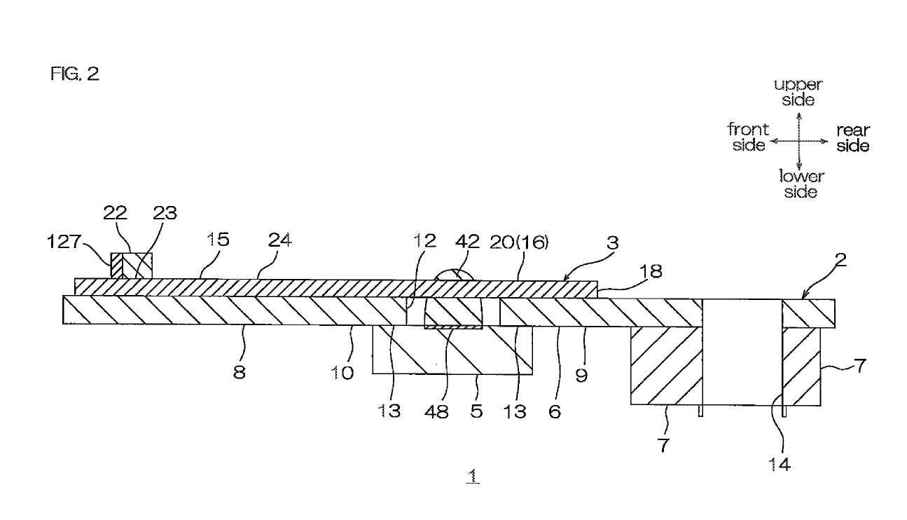

As shown in FIGS. 1 and 2, an assembly 1 is a head stack assembly (HSA) in which a suspension board with circuit 3 that is mounted with a slider 22 mounted with a magnetic head 127 and a piezoelectric element (piezo element) 5, as an electronic element, is supported by a supporting plate 2 to be mounted on a hard disk drive (not shown). The assembly 1 includes the supporting plate 2 and the suspension board with circuit 3 that is provided on the supporting plate 2 and is supported by the supporting plate 2.

The supporting plate 2 is formed so as to extend in the front-rear direction and includes an actuator plate portion 6, a base plate portion 7 that is provided below the actuator plate portion 6, and a load beam portion 8 that is provided at the front side of the actuator plate portion 6 to be continuous thereto.

The actuator plate portion 6 integrally includes a rear plate portion 9, a front plate portion 10 that is provided at the front side of the rear plate portion 9 at spaced intervals thereto, and flexible portions 11 that are provided between the rear plate portion 9 and the front plate portion 10.

The rear plate portion 9 is formed into a generally rectangular shape in plane view at the rear end portion of the actuator plate portion 6.

The front plate portion 10 is formed into a generally rectangular shape in plane view extending in the right-left direction.

The flexible portions 11 are provided at both right and left sides of the actuator plate portion 6. The right-side flexible portion 11 is provided so as to be disposed between the right-side portion of the front end portion of the rear plate portion 9 and the right-side portion of the rear end portion of the front plate portion 10. The left-side flexible portion 11 is provided so as to be disposed between the left-side portion of the front end portion of the rear plate portion 9 and the left-side portion of the rear end portion of the front plate portion 10. Each of the two flexible portions 1 is formed so that the central portion in the front-rear direction thereof curves toward both right and left outer sides and so as to have generally the same width over the front-rear direction. To be specific, the central portion in the front-rear direction of the flexible portion 11 is formed so as to project in a generally U-shape (or generally V-shape) toward both right and left outer sides. Accordingly, although described later, the flexible portion 11 is configured to allow the front plate portion 10 to be distanced from or neared to the rear plate portion 9 by stretching and shrinking of the piezoelectric element 5.

A plate opening portion 12 that is divided by the front surface of the rear plate portion 9, the rear surface of the front plate portion 10, and the inner surfaces in the right-left direction of the flexible portions 11 is provided in the actuator plate portion 6. The plate opening portion 12 passes through the actuator plate portion 6 in the thickness direction.

Two pairs of attaching regions 13 to which the rear end portions and the front end portions of the piezoelectric elements 5 are attached are divided in the front end portion of the rear plate portion 9 and the rear end portion of the front plate portion 10. Each of the two pairs of attaching regions 13 is formed into a generally rectangular shape in bottom view that is long in the right-left direction, corresponding to the front end portion of the rear plate portion 9 and the rear end portion of the front plate portion 10, in the left-side portion or the right-side portion.

The base plate portion 7 is fixed to the central portion in the right-left and front-rear directions of the lower surface of the rear plate portion 9. In plane view, the front portion of the base plate portion 7 is formed into a generally rectangular shape and the rear portion thereof is formed into a generally semicircular shape.

A hole 14 in a generally circular shape in bottom view passing through the central portion of the rear plate portion 9 and that of the base plate portion 7 in the thickness direction is provided in the supporting plate 2.

A drive coil (not shown) for vibrating the front end portion of the assembly 1 with the hole 14 as a center is placed in the base plate portion 7.

The load beam portion 8 is provided integrally with the actuator plate portion 6. To be specific, the load beam portion 8 is formed so as to extend from the front end of the front plate portion 10 toward the front side and is, in plane view, formed into a generally trapezoidal shape in which the width thereof is gradually reduced toward the front side.

The supporting plate 2 is, for example, formed of a metal material such as stainless steel, aluminum, and iron or an alloy thereof. A size of the supporting plate 2 is appropriately set. The actuator plate portion 6 and the load beam portion 8 have a thickness of, for example, 30 μm or more and 150 μm or less. The base plate portion 7 has a thickness of, for example, 150 μm or more and 200 μm or less. The supporting plate 2 serves as an actuator plate/load beam integrated plate that integrally includes the actuator plate portion 6 and the load beam portion 8.

The suspension board with circuit 3 is formed into a generally flat belt shape in plane view extending in the front-rear direction. As shown in FIG. 1, the suspension board with circuit 3 includes a metal supporting board 18 and a conductive layer 19 that is supported by the metal supporting board 18.

The metal supporting board 18 is formed so as to correspond to the outer shape of the suspension board with circuit 3 and integrally includes a wire portion 16, a front portion 15 that is provided at the front side of the wire portion 16, and a rear portion 17 that is provided at the rear side thereof.

The wire portion 16 is formed at the central portion in the front-rear direction of the metal supporting board 18 and integrally includes a linear portion 20 that extends in the front-rear direction and a bent portion 21 that bends from the rear end portion of the linear portion 20 toward the left side to then further bend rearwardly. The linear portion 20 and the bent portion 21 are formed so as to have generally the same width over the front-rear direction. The wire portion 16 supports wires 25 (described later).

The front portion 15 is continuous from the front end of the linear portion 20 and is formed into a generally rectangular shape in plane view that slightly expands toward both right and left outer sides with respect to the wire portion 16. To be specific, the front portion 15 includes a gimbal 23 on which the slider 22 (described later) is mounted and a gimbal rear portion 24 that connects the gimbal 23 to the linear portion 20.

The gimbal 23 is formed into a generally rectangular shape in plane view having a width wider than that of the linear portion 20. The gimbal 23 supports front-side terminals 26 (described later) and is mounted with the slider 22 (described later) having the magnetic head 127 (ref: FIG. 2) that is electrically connected to the front-side terminals 26.

The gimbal rear portion 24 is continuous to the rear end of the gimbal 23 and is formed into a generally triangular shape in which the width thereof is gradually reduced toward the rear side. The gimbal rear portion 24 supports the wires 25.

The rear portion 17 is continuous from the rear end of the bent portion 21 and is formed into a generally rectangular shape in plane view having generally the same width as that of the bent portion 21. The rear portion 17 supports rear-side terminals 27 (describe later).

The conductive layer 19, on the metal supporting board 18, integrally includes the wires 25 extending along the front-rear direction, the front-side terminals 26 that are continuous to the front end portions of the wires 25, and the rear-side terminals 27 that are continuous to the rear end portions of the wires 25.

The wires 25 include signal wires 25A that transmit an electrical signal between the magnetic head 127 (ref: FIG. 2) and a read/write board (not shown) and are disposed over the entire suspension board with circuit 3 in the front-rear direction. A plurality (four pieces) of signal wires 25A are disposed at spaced intervals to each other in the right-left direction.

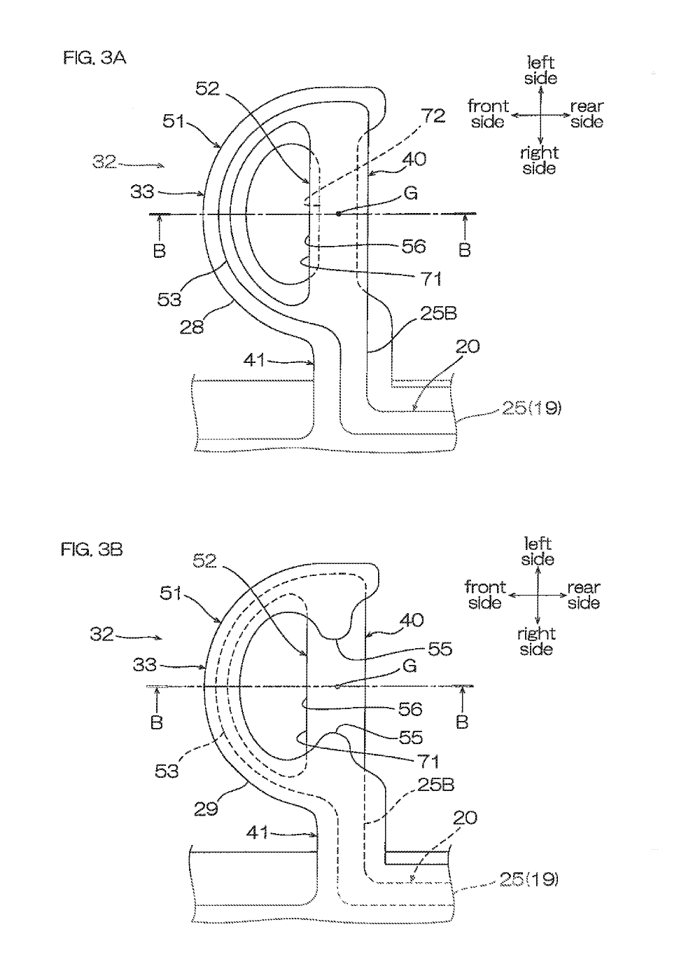

The wires 25 further include a plurality (two pieces) of power supply wires 25B. The power supply wires 25B are electrically connected to power supply-side terminals 27B to be described next and are disposed to be continuous to the power supply-side terminals 27B in the rear portion 17; disposed in parallel at both sides of the signal wires 25A at spaced intervals thereto in the rear portion 17 and the bent portion 21; and disposed to bend toward both right and left outer sides to then reach pad portions 33 (ref: FIGS. 3A and 3B) to be described later at the central portion in the front-rear direction of the linear portion 20.

The front-side terminals 26 are disposed in the front portion 15. To be specific, at the front side of the gimbal 23, a plurality (four pieces) of front-side terminals 26 are disposed at spaced intervals to each other in the right-left direction along the front end surface of the slider 22. The front-side terminals 26 are head-side terminals 26A to which the magnetic head 127 is electrically connected.

The rear-side terminals 27 are disposed in the rear end portion of the rear portion 17. To be specific, a plurality (six pieces) of rear-side terminals 27 are disposed at spaced intervals to each other in the front-rear direction. The rear-side terminals 27 include a plurality (four pieces) of external side terminals 27A, which are continuous to the signal wires 25A and to which a terminal of a read/write board is connected.

The rear-side terminals 27 further include a plurality (two pieces) of power supply-side terminals 27B, which are continuous to the power supply wires 25B and are electrically connected to the piezoelectric elements 5. The power supply-side terminals 27B are disposed at both front and rear sides of the external side terminals 27A at spaced intervals thereto and are electrically connected to a power supply (not shown).

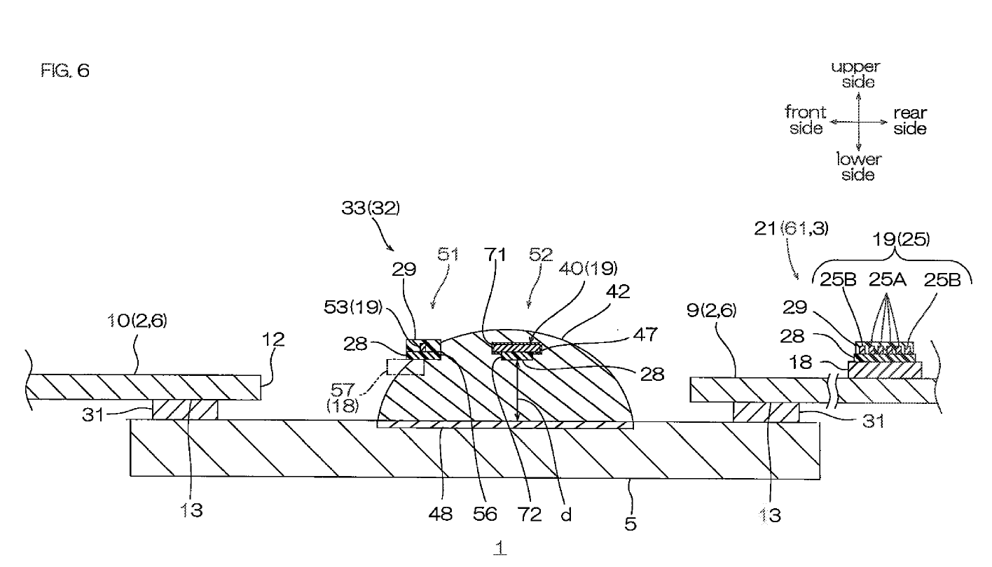

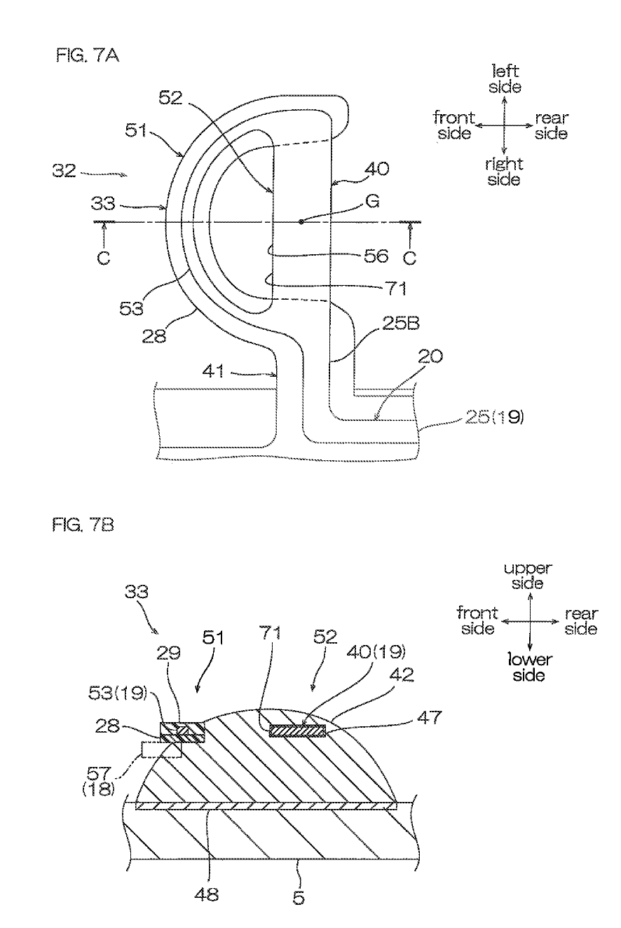

As shown in FIGS. 5G and 6, the suspension board with circuit 3 includes the metal supporting board 18, a base insulating layer 28 that is disposed thereon, the conductive layer 19 that is disposed thereon, and a cover insulating layer 29 that is provided on the base insulating layer 28 so as to cover the wires 25.

The metal supporting board 18 is formed of, for example, a metal material such as stainless steel, 42-alloy, aluminum, copper-beryllium, and phosphor bronze. Preferably, the metal supporting board 18 is formed of stainless steel. The metal supporting board 18 has a thickness of, for example, 10 μm or more, preferably 12 μm or more, or more preferably 14 μm or more, and, for example, 30 μm or less, preferably 25 μm or less, or more preferably 20 μm or less.

As referred in FIG. 1, the base insulating layer 28 is formed into a pattern corresponding to the conductive layer 19 on the upper surface of the metal supporting board 18 in the front portion 15, the wire portion 16, and the rear portion 17. The base insulating layer 28 is formed of an insulating material such as a synthetic resin. Examples thereof include polyimide resin, polyamideimide resin, acrylic resin, polyether nitrile resin, polyether sulfone resin, polyethylene terephthalate resin, polyethylene naphthalate resin, and polyvinyl chloride resin. Preferably, the base insulating layer 28 is formed of a polyimide resin. The base insulating layer 28 has a thickness (maximum thickness) of, for example, 1 μm or more, preferably 2 μm or more, or more preferably 3 μm or more, and, for example, 25 μm or less, preferably 20 μm or less, or more preferably 15 μm or less.

As shown in FIGS. 1 and 5G, the conductive layer 19 is formed into the above-described pattern on the upper surface of the base insulating layer 28 in the front portion 15, the wire portion 16, and the rear portion 17. The conductive layer 19 is formed of a conductive material such as copper, nickel, gold, and solder or an alloy thereof. Preferably, the conductive layer 19 is formed of copper. The conductive layer 19 has a thickness of, for example, 1 μm or more, preferably 2 μm or more, or more preferably 3 μm or more, and, for example, 25 μm or less, preferably 20 μm or less, or more preferably 15 μm or less. Each of the plurality of wires 25 has a width of, for example, 5 μm or more, or preferably 8 μm or more, and, for example, 200 μm or less, or preferably 100 μm or less. An interval between the plurality of wires 25 is, for example, 5 μm or more, or preferably 8 μm or more, and, for example, 1000 μm or less, or preferably 100 μm or less. The front-side terminal 26 and the rear-side terminal 27 have a width and a length of, for example, 20 μm or more, or preferably 30 μm or more, and, for example, 1000 μm or less, or preferably 800 μm or less. An interval between the plurality of front-side terminals 26 and that between the plurality of rear-side terminals 27 are, for example, 20 μm or more, or preferably 30 μm or more, and, for example, 1000 μm or less, or preferably 800 μm or less.

The cover insulating layer 29 is provided, in the wire portion 16, the front portion 15, and the rear portion 17, so as to cover the upper surface of the base insulating layer 28 around the wires 25 and the upper and side surfaces of the wires 25. The cover insulating layer 29 is, although not shown, formed into a pattern of exposing the front-side terminals 26 in the front portion 15 and exposing the rear-side terminals 27 in the rear portion 17. The cover insulating layer 29 is formed of the same insulating material as that of the base insulating layer 28. The cover insulating layer 29 has a thickness of, for example, 1 μm or more, preferably 2 μm or more, or more preferably 3 μm or more, and, for example, 15 μm or less, preferably 10 μm or less, or more preferably 7 μm or less.

As shown in FIGS. 1 and 2, in the suspension board with circuit 3, the lower surface of the metal supporting board 18 is supported by the supporting plate 2. To be specific, the lower surfaces of the wire portion 16 and the front portion 15 are supported by the supporting plate 2 and the lower surface of the rear portion 17 protrudes from the supporting plate 2 rearwardly without being supported by the supporting plate 2.

To be specific, the suspension board with circuit 3 is disposed so that the bent portion 21 is disposed in a generally L-shape along the left end portion and the front end portion of the rear plate portion 9 and the linear portion 20 crosses the central portion in the right-left direction of the plate opening portion 12 from the central portion in the right-left direction of the front end portion of the rear plate portion 9 to then reach the central portion in the right-left direction of the front plate portion 10. The suspension board with circuit 3 is disposed so that the front portion 15 is formed in the central portion in the right-left direction of the load beam portion 8 over the front-rear direction of the load beam portion 8.

The suspension board with circuit 3 is mounted with the piezoelectric elements 5. That is, the suspension board with circuit 3 includes the piezoelectric elements 5.

The piezoelectric elements 5 are placed at the lower side of the supporting plate 2. To be specific, a plurality (two pieces) of piezoelectric elements 5 are provided at spaced intervals to each other in the right-left direction. Each of the two piezoelectric elements 5 is a stretchable actuator (piezo element) in the front-rear direction and is formed into a generally rectangular shape in plane view that is long in the front-rear direction. The piezoelectric elements 5 are disposed so as to stride over the plate opening portion 12 in the front-rear direction. To be specific, each of both front and rear end portions of the two piezoelectric elements 5 adheres to each of the attaching regions 13 (ref: the dashed lines in FIG. 1) both in the front end portion of the rear plate portion 9 and the rear end portion of the front plate portion 10 via an adhesive layer 31 (ref: the dashed line in FIG. 1) to be fixed.

As shown in FIG. 6, an electrode 48 is provided in the central portion in the front-rear direction of each of the upper surfaces of the two piezoelectric elements 5 and the electrodes 48 are bonded to the pad portions 33 to be described next.

The electricity is supplied from the conductive layer 19 and the voltage thereof is controlled, so that a pair of piezoelectric elements 5 stretch and shrink.

Next, connecting arms 32 in the suspension board with circuit 3 are described in detail with reference to FIGS. 3A, 3B, and 5G

As shown in FIG. 1, the suspension board with circuit 3 includes a pair of connecting arms 32.

Each of a pair of connecting arms 32 is provided so as to protrude in an arm shape from the central portion in the front-rear direction of the linear portion 20 toward both right and left outer sides. To be specific, the left-side connecting arm 32 protrudes from the linear portion 20 toward the left side. The right-side connecting arm 32 is configured to be line symmetrical with respect to the linear portion 20. Thus, hereinafter, the detailed description of the right-side connecting arm 32 is omitted and the left-side connecting arm 32 is described in detail.

As shown in FIGS. 3A and 3B, the left-side connecting arm 32 includes the pad portion 33 that is disposed at the left side of the linear portion 20 at spaced intervals thereto and a joint portion 41 that connects the linear portion 20 to the pad portion 33.

The pad portion 33 is configured to be bonded to the piezoelectric element 5. To be specific, the pad portion 33 is formed into a generally inverted D-shape in plane view. To be more specific, the pad portion 33 includes a terminal supporting portion 51 in a generally semicircular arc shape (or generally U-shape) in plane view having an opening rearwardly and a connecting portion 52 that connects a pair of rear end portions (free end portions) of the terminal supporting portion 51.

As shown in FIG. 5G, the terminal supporting portion 51 includes the base insulating layer 28, a supporting conductor 53 that is provided on the base insulating layer 28, and the cover insulating layer 29 that is provided on the base insulating layer 28 so as to cover the supporting conductor 53.

As shown in FIGS. 3A and 5G, in the terminal supporting portion 51, the base insulating layer 28 is formed as the same layer as the base insulating layer 28 in the linear portion 20. The base insulating layer 28 in the terminal supporting portion 51 is formed into a pattern corresponding to the outer shape of the terminal supporting portion 51. To be specific, the base insulating layer 28 in the terminal supporting portion 51 is formed into a generally semicircular arc shape in plane view.

In the terminal supporting portion 51, the supporting conductor 53 is formed of the above-described conductive layer 19 and, to be specific, is provided as the same layer as the power supply wire 25B. In the terminal supporting portion 51, the supporting conductor 53 is, in plane view, formed into a pattern of being included in the base insulating layer 28. That is, the supporting conductor 53 is formed to have a narrow width with respect to the base insulating layer 28 in the terminal supporting portion 51 and, to be specific, is disposed between the inner peripheral edge and the outer peripheral edge of the base insulating layer 28 in the terminal supporting portion 51. To be more specific, the supporting conductor 53 is formed into a generally semicircular arc shape in plane view that is included in a generally circular arc shape in plane view of the base insulating layer 28 in the terminal supporting portion 51.

As shown in FIGS. 3B and 5G, in the terminal supporting portion 51, the cover insulating layer 29 is, in plane view, formed into the same pattern as that of the base insulating layer 28. The cover insulating layer 29 in the terminal supporting portion 51 covers the upper and side surfaces of the supporting conductor 53 and a portion of the upper surface that is exposed from the supporting conductor 53 in the base insulating layer 28.

As shown in FIGS. 3A and 3B, the connecting portion 52 is formed into a generally linear shape (or generally I-shape) in plane view extending in the right-left direction and both right and left end portions thereof are supported by the terminal supporting portion 51. As shown in FIG. 5G, the connecting portion 52 includes the base insulating layer 28, a piezoelectric-side terminal 40 that is provided on (at one side in the thickness direction of or at one side in the penetrating direction of a through hole 56 of) the base insulating layer 28, and the cover insulating layer 29 (ref: FIG. 3B) that is provided on the base insulating layer 28 so as to partially cover the piezoelectric-side terminal 40.

As shown in FIG. 3A, in the connecting portion 52, the base insulating layer 28 is provided integrally with the base insulating layer 28 in the terminal supporting portion 51 and, to be specific, is formed into a pattern of connecting a pair of rear end portions of the base insulating layer 28 in the terminal supporting portion 51. The base insulating layer 28 in the connecting portion 52 is formed into a generally linear shape extending in the right-left direction and, to be specific, is formed to have generally the same width as that of the base insulating layer 28 in the terminal supporting portion 51.

The piezoelectric-side terminal 40 is provided to be continuous to the supporting conductor 53 in the terminal supporting portion 51 and is formed of the same conductive layer 19 as that of the supporting conductor 53. To be specific, the piezoelectric-side terminal 40 is formed into a pattern of connecting a pair of rear end portions of the supporting conductor 53. To be more specific, the piezoelectric-side terminal 40 is formed into a generally linear shape extending in the right-left direction and, to be specific, is formed to have a wide width with respect to the supporting conductor 53.

To be more specific, as shown in FIGS. 3A and 5G, the piezoelectric-side terminal 40 is formed to have a wide width with respect to the base insulating layer 28 in the connecting portion 52. To be specific, each of the front and rear end portions of the piezoelectric-side terminal 40 protrudes from each of the front and rear peripheral edges of the base insulating layer 28 in the connecting portion 52 toward each of the front and rear directions. In this manner, both front and rear end portions of the lower surface of the piezoelectric-side terminal 40 are exposed from the base insulating layer 28 in the connecting portion 52.

As shown in FIG. 3B, in the connecting portion 52, the cover insulating layer 29 is provided integrally with the cover insulating layer 29 in the terminal supporting portion 51 and, to be specific, is formed into a pattern of forming protruding portions 55 that protrude from a pair of rear end portions of the cover insulating layer 29 in the terminal supporting portion 51 inwardly in the right-left direction. Each of a pair of protruding portions 55 covers each of both right and left end portions of the piezoelectric-side terminal 40. Meanwhile, each of the protruding portions 55 exposes the central portion in the right-left direction of the upper surface of the piezoelectric-side terminal 40. Each of a pair of protruding portions 55 projects in a generally V-shape (or generally tapered shape) in plane view in which an overlapped portion with the piezoelectric-side terminal 40 is gradually reduced toward the inner side in the right-left direction.

The pad portion 33 has the through hole 56.

As shown in FIG. 5G, the through hole 56 has an opening so as to pass through the pad portion 33 in the thickness direction. As shown in FIG. 3A, the periphery of the through hole 56 is closed by the pad portion 33. To be specific, the through hole 56 is surrounded by the terminal supporting portion 51 and the connecting portion 52. As shown in FIGS. 3A and 3B, in the through hole 56, the front end edge thereof is formed into a curved shape that expands toward the front side. The rear end edge thereof is formed into a linear shape that extends in the right-left direction. The front-side portion and both right-side and left-side portions of the inner peripheral surface in the through hole 56 are divided only by the base insulating layer 28 and the cover insulating layer 29. On the other hand, the rear-side portion of the inner peripheral surface in the through hole 56 is divided only by the piezoelectric-side terminal 40. That is, as shown in FIGS. 3A and 5G, the rear-side portion of an inner peripheral surface 71 of the piezoelectric-side terminal 40 in the connecting portion 52 is disposed at the inner side (front side) of an inner peripheral surface 72 facing the through hole 56 in the base insulating layer 28.

As shown in FIG. 5G, in the connecting portion 52, a space divided by the upper side of the piezoelectric-side terminal 40, by the front and rear sides thereof, by the front and rear sides of the base insulating layer 28, by a portion of the lower side that is exposed from the base insulating layer 28 in the piezoelectric-side terminal 40, and by the lower side of the base insulating layer 28 is, in side sectional view, continuous as a region surrounding the connecting portion 52.

As shown in FIGS. 3A and 3B, the joint portion 41 connects the left end portion of the central portion in the front-rear direction of the linear portion 20 to the right end portion of the terminal supporting portion 51 in the pad portion 33.

The joint portion 41 is formed into a generally rectangular shape in plane view extending in the right-left direction. The joint portion 41 includes the base insulating layer 28, the power supply wire 25B that is provided on the base insulating layer 28, and the cover insulating layer 29 that is provided on the base insulating layer 28 so as to cover the power supply wire 25B.

In the joint portion 41, the base insulating layer 28 is formed into a shape corresponding to the outer shape of the joint portion 41. The base insulating layer 28 in the joint portion 41 is formed to be continuous to the base insulating layer 28 in the linear portion 20 and to the base insulating layer 28 in the right-side rear end portion of the terminal supporting portion 51.

In the joint portion 41, the power supply wire 25B is formed to extend in the right-left direction and is formed to be continuous to the power supply wire 25B in the linear portion 20 and to the right-side rear end portion of the supporting conductor 53 in the terminal supporting portion 51.

The cover insulating layer 29 in the joint portion 41 is formed into the same pattern as that of the base insulating layer 28 in the joint portion 41.

The base insulating layer 28 and the cover insulating layer 29 in the terminal supporting portion 51, and the base insulating layer 28 in the connecting portion 52 have a width of, for example, 40 μm or more, or preferably 60 μm or more, and, for example, 500 μm or less, or preferably 200 μm or less. The supporting conductor 53 has a width of, for example, 10 μm or more, or preferably 15 μm or more, and, for example, 440 μm or less, or preferably 140 μm or less. The piezoelectric-side terminal 40 has a width of, for example, 40 μm or more, or preferably 80 μm or more, and, for example, 500 μm or less, or preferably 200 μm or less. Each of a pair of protruding portions 55 has a protruding length in the right-left direction of, for example, 5 μm or more, or preferably 10 μm or more, and, for example, 100 μm or less, or preferably 50 μm or less. The through hole 56 has a length in the front-rear direction of, for example, 80 μm or more, or preferably 100 μm or more, and, for example, 500 μm or less, or preferably 300 μm or less. The through hole 56 has a length in the right-left direction of, for example, 80 μm or more, or preferably 100 μm or more, and, for example, 500 μm or less, or preferably 300 μm or less.

As shown in FIG. 5G, in the suspension board with circuit 3, a plating layer 47 is provided on each of the surfaces of a plurality of terminals, to be specific, the front-side terminals 26 (ref: FIG. 1), the rear-side terminals 27 (ref: FIG. 1), and the piezoelectric-side terminals 40.

In the connecting portion 52, the plating layer 47 is provided on the upper, side, and lower surfaces of the piezoelectric-side terminal 40. To be more specific, the plating layer 47 is, on the upper surface of the piezoelectric-side terminal 40, provided in a region (to be specific, midway portion in the right-left direction) that is exposed from the protruding portions 55 in the cover insulating layer 29. The plating layer 47 is also provided on the entire both front-side and rear-side surfaces of the piezoelectric-side terminal 40. The plating layer 47 is, on the lower surface of the piezoelectric-side terminal 40, provided in a region (to be specific, both front and rear end portions) that is exposed from the base insulating layer 28.

The plating layer 47 is, for example, formed of a plating material such as nickel and gold or an alloy thereof. Preferably, the plating layer 47 is formed of gold. The plating layer 47 has a thickness of, for example, 0.1 μm or more, preferably 0.2 μm or more, or more preferably 0.3 μm or more, and, for example, 5 μm or less, preferably 4.5 μm or less, or more preferably 4 μm or less.

Next, a method for producing the assembly 1 is described.

In order to produce the assembly 1, first, the suspension board with circuit 3 (the suspension board with circuit 3 in which the piezoelectric elements 5 are not yet included), the supporting plate 2, and the piezoelectric elements 5 are prepared or produced.

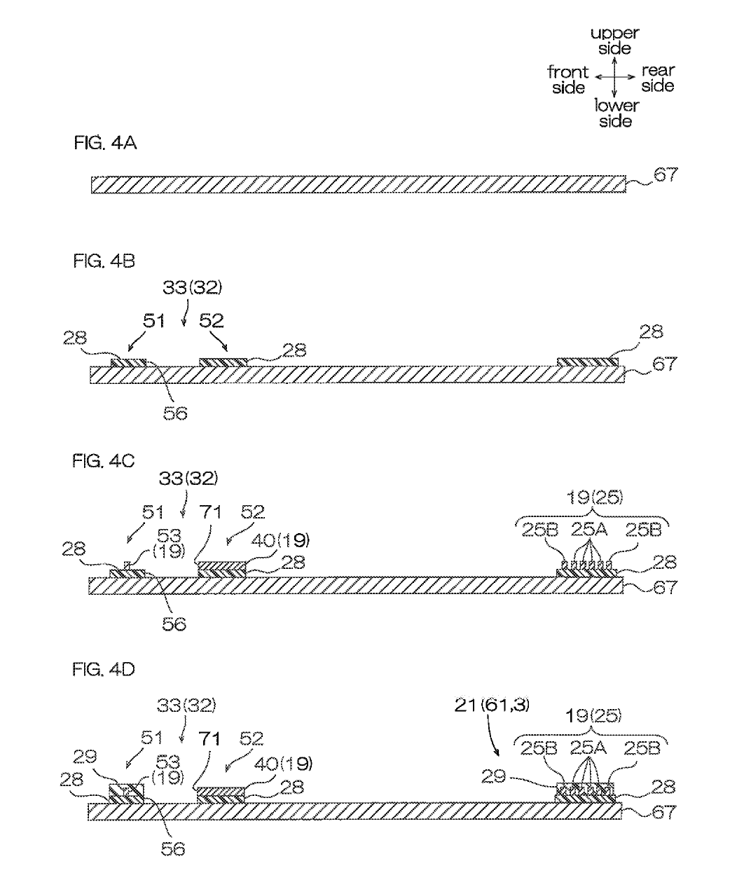

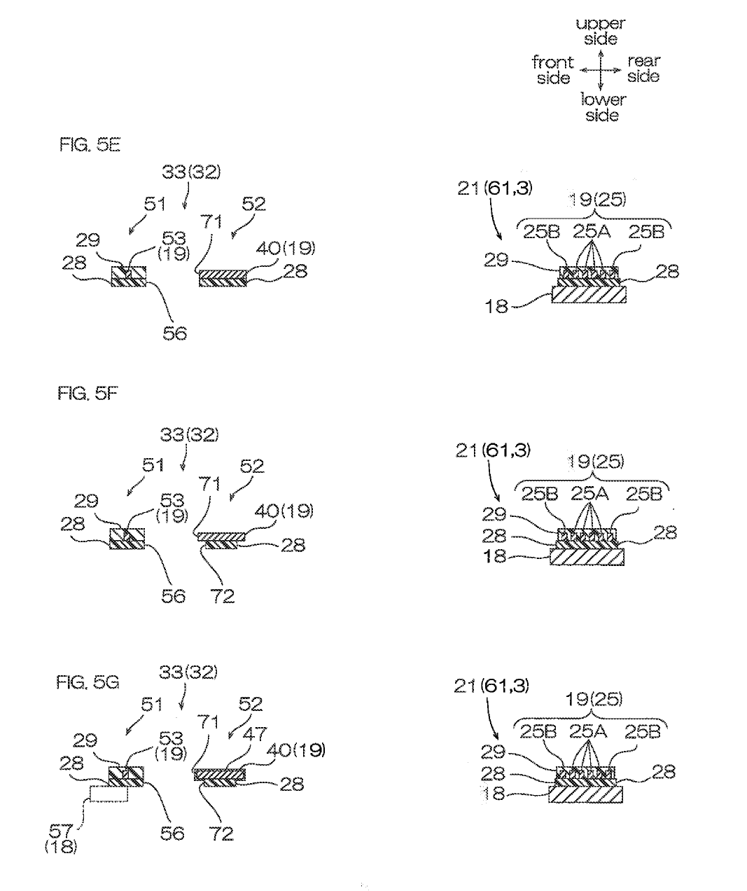

Next, a method for producing the suspension board with circuit 3 is described with reference to FIGS. 4A to 4D and FIGS. 5E to 5G

In this method, as shown in FIG. 4A, first, a metal supporting layer 67 is prepared.

The metal supporting layer 67 is a board for forming the metal supporting board 18 (ref: FIG. 5E) and the material and the thickness thereof are the same as those of the above-described metal supporting board 18.

Next, as shown in FIG. 4B, the base insulating layer 28 is provided on the metal supporting layer 67. The base insulating layer 28 in the connecting portion 52 is formed in the same pattern as that of the piezoelectric-side terminal 40 to be provided next.

To be specific, the base insulating layer 28 is, on the metal supporting layer 67, formed into a pattern of including the through hole 56. In order to provide the base insulating layer 28, first, for example, a varnish of a photosensitive insulating material is applied onto the upper surface of the metal supporting layer 67 to be then dried, so that a photosensitive base film is formed. Next, the photosensitive base film is exposed to light and developed to be then, if necessary, cured. Or, the base insulating layer 28 that is formed into the above-described pattern in advance is provided on the upper surface of the metal supporting layer 67.

Next, as shown in FIG. 4C, the conductive layer 19 is provided on the upper surface of the base insulating layer 28. To be specific, the conductive layer 19 is formed into a pattern of including the supporting conductor 53 and the piezoelectric-side terminal 40 in the pad portion 33 by an additive method, a subtractive method, or the like.

Next, as shown in FIG. 4D, the cover insulating layer 29 is provided in the above-described pattern. To be specific, the cover insulating layer 29 is formed into a pattern of including the protruding portions 55 (ref: FIG. 3B) in the same method as the forming method of the base insulating layer 28.

Next, as shown in FIG. 5E, the metal supporting board 18 in the above-described pattern is formed by trimming the metal supporting layer 67. To be specific, the metal supporting layer 67 is formed into the shape of the metal supporting board 18 by, for example, an etching method such as dry etching (for example, plasma etching) and wet etching (for example, chemical etching), drilling, or laser processing. Preferably, the metal supporting layer 67 is trimmed by wet etching.

In this manner, the metal supporting layer 67 corresponding to the connecting arms 32 (ref: FIGS. 3A and 3B) is removed.

Next, as shown in FIG. 5F, the base insulating layer 28 in the connecting portion 52 is processed into the above-described pattern. To be specific, both front and rear end portions of the base insulating layer 28 in the connecting portion 52 are removed. To be specific, the above-described base insulating layer 28 is removed by, for example, etching, or preferably wet etching or the like.

In this manner, both front and rear end portions of the lower surface of the piezoelectric-side terminal 40 are exposed from the base insulating layer 28.

Thereafter, as shown in FIG. 5G, the plating layer 47 is formed on the surfaces of the front-side terminals 26 (ref: FIG. 1), the rear-side terminals 27 (ref: FIG. 1), and the piezoelectric-side terminals 40 by, for example, plating such as electroless plating and electrolytic plating, or preferably electrolytic plating.

In this manner, the suspension board with circuit 3 is produced.

Next, as shown in FIGS. 1 and 2, the suspension board with circuit 3 produced as described above, the supporting plate 2, and the piezoelectric elements 5 are assembled.

To be specific, as shown in FIG. 2, first, the suspension board with circuit 3 is disposed on the upper surface of the supporting plate 2. That is, as shown in FIG. 1, the suspension board with circuit 3 is fixed to the supporting plate 2 by, for example, welding or an adhesive. Also, the suspension board with circuit 3 is fixed to the supporting plate 2 so that the connecting arms 32 are disposed in the plate opening portion 12.

Thereafter, as shown in FIG. 6, both front and rear end portions of the piezoelectric element 5 is fixed to the supporting plate 2 and the electrode 48 in the piezoelectric element 5 is bonded to the pad portion 33.

In order to fix the piezoelectric element 5 to the supporting plate 2, the adhesive layer 31 is set in the attaching region 13 in the actuator plate portion 6 and each of both front and rear end portions of the piezoelectric element 5 is attached to the attaching region 13 via the adhesive layer 31. In this manner, the piezoelectric elements 5 are, in the plate opening portion 12, disposed at spaced intervals to each other at both right and left outer sides of the linear portion 20 in the suspension board with circuit 3.

As shown in FIG. 6, in order to bond the electrode 48 in the piezoelectric element 5 to the pad portion 33, first, a bonding material 42 is provided between the electrode 48 and the pad portion 33.

To be specific, as referred in FIGS. 3A and 3B, the bonding material 42 is, in plane view, disposed on the upper surface of the electrode 48 so that the center of gravity G of the bonding material 42 is overlapped with the center in the right-left direction of the connecting portion 52.

Examples of a material for forming the bonding material 42 include a low-temperature connecting medium (for example, electrically conductive paste such as gold paste or silver paste and low-melting solder) that develops adhesive properties by heating at a relatively low temperature (for example, 100° C. or more and below 200° C.) and a high-temperature connecting medium (for example, solder) that develops adhesive properties by heating at a relatively high temperature (for example, 200° C. or more and 300° C. or less). Preferably, a low-temperature connecting medium is used so as to prevent damage of the piezoelectric element 5 by heating.

The bonding material 42 is set at such an amount of, in side sectional view, capable of embedding the piezoelectric-side terminal 40 and filling the through hole 56.

The bonding material 42 is disposed as described above to be then heated. When the bonding material 42 is formed of a low-temperature connecting medium, it is heated at a relatively low temperature, to be specific, at, for example, 100° C. or more and 120° C. or less.

In this manner, the bonding material 42 flows on the electrode 48. Then, from the lower side of the pad portion 33, the bonding material 42, in side view, sandwiches the connecting portion 52 from both front and rear sides thereof and next, reaches the upper side of the connecting portion 52. To be more specific, the bonding material 42 reaches a space at the upper side of the piezoelectric-side terminal 40 from a space at the lower side of the base insulating layer 28 and the piezoelectric-side terminal 40 via a space at the front and rear sides of the base insulating layer 28 and the piezoelectric-side terminal 40. In this manner, the bonding material 42, in side view, embeds the connecting portion 52 and fills the through hole 56. That is, the bonding material 42 is provided so as to continuously surround the upper, lower, front, and rear sides of the connecting portion 52. That is, the bonding material 42 is provided so as to continuously surround the upper side of the piezoelectric-side terminal 40, the front and rear sides thereof, the front and rear sides of the base insulating layer 28, a portion of the lower side that is exposed from the base insulating layer 28 in the piezoelectric-side terminal 40, and the lower side of the base insulating layer 28.

In the connecting portion 52, the bonding material 42 is in contact with the surface of the plating layer 47 that is formed on the surface of the piezoelectric-side terminal 40, and is also in contact with the surface of the base insulating layer 28 and the surfaces of the protruding portions 55 (ref: FIG. 3B) in the cover insulating layer 29.

Also, the bonding material 42 is in contact with the rear-side surface (inner-side surface that divides the through hole 56) of the cover insulating layer 29 in the terminal supporting portion 51 and the rear-side surface (inner-side surface) and lower surface of the base insulating layer 28 in the terminal supporting portion 51.

In this manner, the pad portion 33 is bonded to the electrode 48 via the bonding material 42 and the piezoelectric-side terminal 40 is electrically connected to the electrode 48 via the bonding material 42.

In this manner, the electrode 48 is bonded to the pad portion 33.

As shown in FIGS. 1 and 2, the slider 22 that is mounted with the magnetic head 127 is mounted on the gimbal 23, so that the magnetic head 127 is electrically connected to the front-side terminals 26.

Furthermore, a read/write board (not shown) is electrically connected to the external side terminals 27A and a power source (not shown) is electrically connected to the power source-side terminals 27B.

Then, a drive coil (not shown) is placed in the base plate portion 7.

In this manner, the assembly 1 is obtained.

The assembly 1 is mounted on a hard disk drive (not shown). In the hard disk drive, while the slider 22 relatively runs in a circumferential direction with respect to the rotating disk-shaped hard disk and floats at minute spaced intervals to the surface of the hard disk, the magnetic head 127 moves in a radial direction of the hard disk based on driving of the drive coil and in this way, the assembly 1 reads and writes information.

Furthermore, the position of the magnetic head 127 with respect to the hard disk drive is finely adjusted by stretching and shrinking (not shown) of the piezoelectric element 5.

According to the suspension board with circuit 3, when the bonding material 42 is provided in the pad portion 33 and the pad portion 33 is bonded to the piezoelectric element 5, the pad portion 33 can fill the through hole 56 and the inner peripheral surface 71, facing the through hole 56 in the pad portion 33, which is divided only by the piezoelectric-side terminal 40 (conductive layer 19) can be covered with the bonding material 42 in an embedded state. Thus, the bonding strength of the piezoelectric element 5 with the pad portion 33 can be improved. As a result, the electrical connection reliability of the piezoelectric element 5 with the conductive layer 19 in the pad portion 33 can be improved.

In the suspension board with circuit 3, the pad portion 33 includes the base insulating layer 28 that is disposed on the upper surface of the piezoelectric-side terminal 40. Thus, the base insulating layer 28 can reinforce the piezoelectric-side terminal 40 in the pad portion 33.

Meanwhile, the rear-side portion of the inner peripheral surface 71 in the pad portion 33 is disposed at the inner side (front side) of the through hole 56 with respect to the inner peripheral surface 72 facing the through hole 56 in the base insulating layer 28. That is, the rear-side portion of the inner peripheral surface 71 in the pad portion 33 is disposed so as to protrude toward the inner side (front side) of the through hole 56 with respect to the inner peripheral surface 72 of the base insulating layer 28, so that when the bonding material 42 is provided in the pad portion 33 and the pad portion 33 is bonded to the piezoelectric element 5, the rear-side portion of the inner peripheral surface 71 in the pad portion 33 is embedded in the bonding material 42. Thus, the bonding strength of the piezoelectric element 5 with the pad portion 33 can be further improved. As a result, the electrical connection reliability of the piezoelectric element 5 with the piezoelectric-side terminal 40 in the pad portion 33 can be further improved.

In the suspension board with circuit 3, the bonding material 42 embeds the connecting portion 52. Thus, the bonding material 42 can improve the bonding strength of the piezoelectric element 5 with the connecting portion 52. As a result, the bonding material 42 can improve the electrical connection reliability of the piezoelectric element 5 with the connecting portion 52.

In the suspension board with circuit 3, the bonding material 42 is provided so as to continuously surround the upper side of the connecting portion 52, the lower side thereof, and both front and rear sides thereof. Thus, the bonding material 42 can surely embed the connecting portion 52 and further improve the bonding strength of the piezoelectric element 5 with the connecting portion 52.

The suspension board with circuit 3 includes the base insulating layer 28 and the conductive layer 19 including the piezoelectric-side terminal 40. The connecting portion 52 includes the base insulating layer 28 and the piezoelectric-side terminal 40. Thus, the base insulating layer 28 can reinforce the piezoelectric-side terminal 40 in the connecting portion 52.

Additionally, the bonding material 42 is provided so as to continuously surround the upper, lower, front, and rear sides of the base insulating layer 28 and the piezoelectric-side terminal 40 in the connecting portion 52. Thus, the bonding material 42 can further improve the bonding strength of the piezoelectric element 5 with the connecting portion 52.

An amount of the bonding material 42 is required to be accurately adjusted in accordance with a distance “d” (length in the thickness direction) between the lower surface of the connecting portion 52 and the upper surface of the electrode 48. According to the first embodiment, however, the amount thereof simply has to be set enough to be capable of embedding the connecting portion 52. Thus, the amount of the bonding material 42 is not required to be accurately adjusted as described above. That is, even when the amount of the bonding material 42 is excessive, the bonding material 42 just passes through the through hole 56 and as long as the bonding material 42 is capable of embedding the connecting portion 52, the piezoelectric-side terminal 40 can be surely electrically connected to the electrode 48.

Furthermore, even when the above-described distance “d” varies, the connecting portion 52 can be electrically connected to the electrode 48 with the bonding material 42 having an amount allowing the bonding material 42 to pass through the through hole 56 to be capable of embedding the connecting portion 52.

Thus, the piezoelectric elements 5 can be easily assembled with the suspension board with circuit 3 and in this manner, the assembly 1 can be obtained.

### Modified Example of First Embodiment

As shown by the phantom line in FIG. 6, the terminal supporting portion 51 can also further include a supporting board 57.

The supporting board 57 is provided on the lower surface of the front-side portion of the base insulating layer 28 in the terminal supporting portion 51. To be specific, the supporting board 57 is, in bottom view, formed into a pattern of including the outer peripheral edge of the base insulating layer 28 in the terminal supporting portion 51. To be more specific, as referred in FIG. 3B, the supporting board 57 is, in bottom view, formed into a pattern in which it is a generally semicircular arc shape in plane view (or generally U-shape) having an opening rearwardly; the inner peripheral edge of the supporting board 57 is overlapped with that of the supporting conductor 53; and the outer peripheral edge of the supporting board 57 is disposed at the outer side with respect to the outer peripheral edge of the base insulating layer 28 at spaced intervals thereto.

The supporting board 57 is formed in a step of trimming the metal supporting layer 67 shown in the above-described FIG. 5E.

In the suspension board with circuit 3, the same function and effect as that described above can be achieved. Furthermore, the terminal supporting portion 51 includes the supporting board 57, so that the stiffness of the terminal supporting portion 51 can be improved. Thus, the connecting portion 52 can be further more strongly supported and, as a result, the bonding strength of the piezoelectric element 5 with the connecting portion 52 can be further improved.

### Second Embodiment

The suspension board with circuit 3 in the second embodiment is described with reference to FIGS. 7A and 7B. In the second embodiment, the same reference numerals are provided for members corresponding to each of those in the above-described first embodiment, and their detailed description is omitted.

In the above-described first embodiment, as shown in FIGS. 5G and 6, the connecting portion 52 includes the base insulating layer 28. Alternatively, in the second embodiment, as shown in FIGS. 7A and 7B, the connecting portion 52 can be also configured without including the base insulating layer 28.

In the connecting portion 52, the plating layer 47 is formed on the lower surface of the piezoelectric-side terminal 40. The surface of the plating layer 47 that is formed on the lower surface of the piezoelectric-side terminal 40 is exposed. That is, the plating layer 47 that is formed on the surface of the piezoelectric-side terminal 40 exposes both upper and lower surfaces and both front and rear surfaces thereof.

In the connecting portion 52, a space divided by the upper side of the piezoelectric-side terminal 40, by the front and rear sides thereof, and by the lower side thereof is, in side sectional view, continuous as a region surrounding the connecting portion 52.

When the bonding material 42 is provided in the pad portion 33 in the suspension board with circuit 3 and the pad portion 33 is bonded to the piezoelectric element 5, the bonding material 42 can be easily and surely brought into contact with both upper and lower surfaces of the conductive layer 19. Thus, the bonding strength of the piezoelectric element 5 with the pad portion 33 can be further improved. As a result, the electrical connection reliability of the electronic element 5 with the conductive layer 19 in the pad portion 33 can be further improved.

The suspension board with circuit 3 includes the conductive layer 19 including the piezoelectric-side terminal 40 and the connecting portion 52 includes the piezoelectric-side terminal 40 without including the base insulating layer 28. Thus, a contact area of the piezoelectric-side terminal 40 with the bonding material 42 can be increased, compared to the first embodiment (ref: FIGS. 5G and 6) in which the piezoelectric-side terminal 40 is supported by the base insulating layer 28.

Additionally, the bonding material 42 is provided so as to continuously surround the upper, lower, front, and rear sides of the piezoelectric-side terminal 40 in the connecting portion 52. Thus, the bonding material 42 can improve the electrical connection reliability of the piezoelectric element 5 with the connecting portion 52.

### Modified Example of Second Embodiment

As shown by the phantom line in FIG. 7B, the terminal supporting portion 51 can also further include the supporting board 57.

The shape, arrangement, producing method, and function and effect of the supporting board 57 are the same as those in modified examples of the above-described first embodiment.

### Third Embodiment

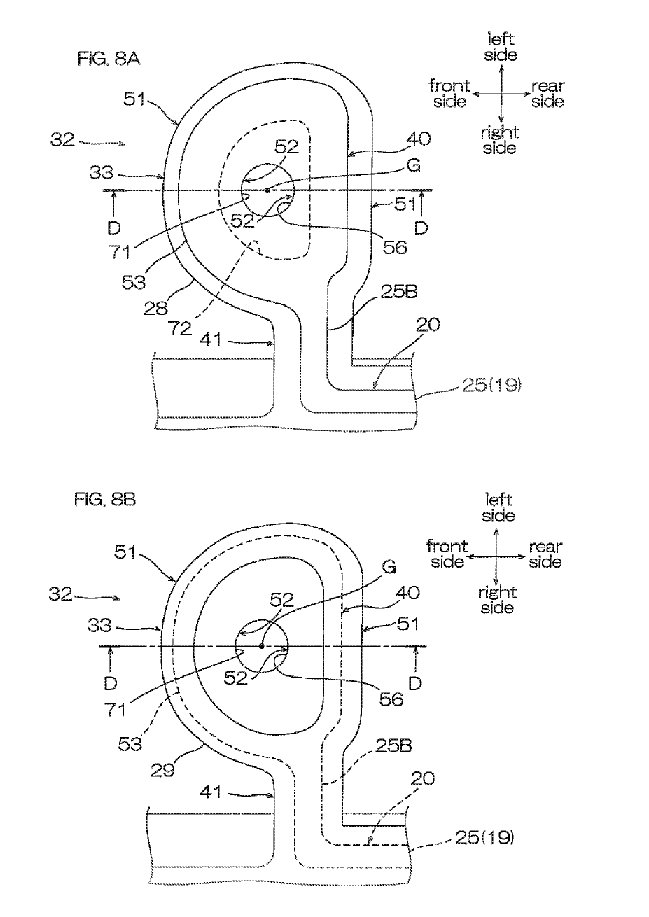

The suspension board with circuit 3 in the third embodiment is described with reference to FIGS. 8A to 11G. In the third embodiment, the same reference numerals are provided for members corresponding to each of those in the above-described first and second embodiments, and their detailed description is omitted.

In the above-described first and second embodiments, as shown in FIGS. 3A, 3B, 7A, and 7B, each of the base insulating layer 28 and the cover insulating layer 29 in the pad portion 33 is formed into a generally semicircular arc shape (or generally U-shape) in plane view. Alternatively, in the third embodiment, as shown in FIGS. 8A and 8B, each of the base insulating layer 28 and the cover insulating layer 29 in the pad portion 33 can be also formed into a generally annulus ring shape (or generally inverted D-shape) in plane view.

That is, the terminal supporting portion 51 serves as the outer shape of the pad portion 33 and the connecting portion 52 is provided at the inner side of the terminal supporting portion 51.

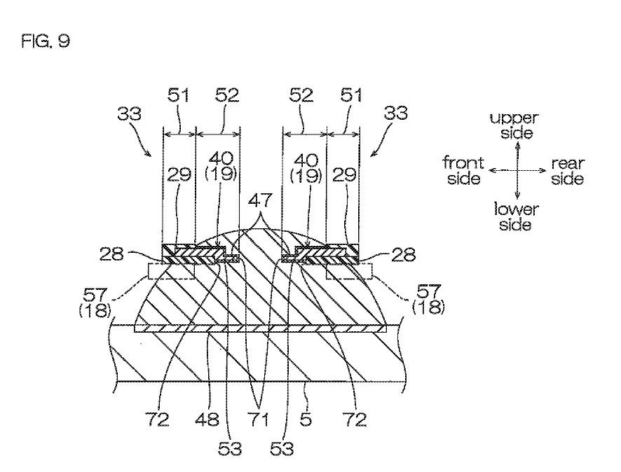

The terminal supporting portion 51 is formed into a generally annulus ring shape (or generally inverted D-shape) in plane view. As shown in FIG. 9, the terminal supporting portion 51 is formed into a pattern of corresponding to the cover insulating layer 29. The terminal supporting portion 51 includes the base insulating layer 28, the supporting conductor 53, and the cover insulating layer 29.

In the terminal supporting portion 51, the base insulating layer 28 is formed into a generally annulus ring shape (or generally inverted D-shape) in plane view.

The supporting conductor 53 is, in plane view, formed into a pattern in which the outer peripheral edge thereof is included in the base insulating layer 28. To be specific, the outer peripheral edge of the supporting conductor 53 is formed into a generally circular shape (or generally inverted D-shape) in plane view that is smaller than the generally circular shape (or generally inverted D-shape) in plane view of the base insulating layer 28.

The cover insulating layer 29 is, in plane view, formed into a pattern in which the outer peripheral edge thereof is disposed at the same position as that of the base insulating layer 28 and the inner peripheral edge thereof is disposed at the central portion in the widthwise direction of the supporting conductor 53.

The connecting portion 52 is formed into a pattern of continuously projecting from the inner peripheral edge of the terminal supporting portion 51 inwardly and dividing the through hole 56. The terminal supporting portion 51 includes the base insulating layer 28 and the piezoelectric-side terminal 40.

The base insulating layer 28 in the connecting portion 52 projects from the inner peripheral edge of the base insulating layer 28 in the terminal supporting portion 51 inwardly.

The piezoelectric-side terminal 40 is formed to be continuous to the upper and inner sides of the base insulating layer 28. To be specific, the piezoelectric-side terminal 40 is formed so as to project inwardly along the upper surface of the base insulating layer 28; then fall downwardly along the inner-side surface of the base insulating layer 28; and thereafter, project slightly inwardly. In the piezoelectric-side terminal 40, the lower surface of a portion that is formed at the inner side with respect to the inner peripheral edge of the base insulating layer 28 is disposed so as to be overlapped with the base insulating layer 28 in the connecting portion 52, when projected in the front-rear and right-left directions. That is, the lower surface of the inner-side portion of the piezoelectric-side terminal 40 is positioned between the upper surface and the lower surface of the base insulating layer 28 in the connecting portion 52. Also, the entire inner peripheral surface 71 facing the through hole 56 in the pad portion 33 is divided only by the conductive layer 19. To be specific, the entire inner peripheral surface 71 in the pad portion 33 is divided only by the plating layer 47 that is provided in the piezoelectric-side terminal 40.

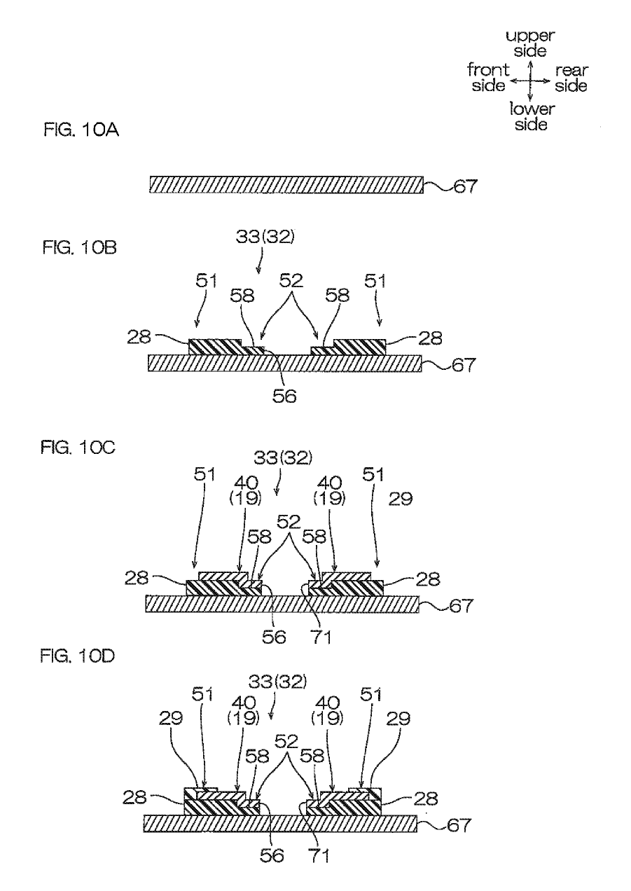

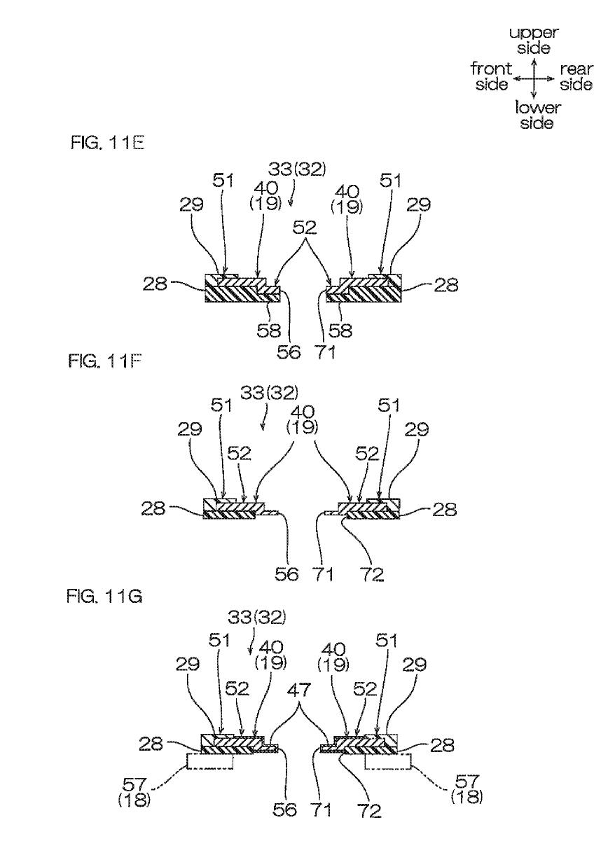

A method for producing the suspension board with circuit 3 including the pad portion 33 is described with reference to FIGS. 10A to 10D and 11E to 11G.

In this method, as shown in FIG. 10A, first, the metal supporting layer 67 is prepared.

Next, as shown in FIG. 10B, the base insulating layer 28 is provided on the metal supporting layer 67 in the above-described pattern so as to form a thin portion 58.

The thin portion 58 is a region that is removed in a subsequent step of removing the base insulating layer 28 (ref: FIG. 11F) and is formed as a region that is thinner than another portion.

In order to provide the base insulating layer 28, for example, a varnish of a photosensitive insulating material is applied onto the upper surface of the metal supporting layer 67 to be then dried, so that a photosensitive base film is provided and next, the photosensitive base film is subjected to gradation exposure to light and developed to be then, if necessary, cured.

Next, as shown in FIG. 10C, the conductive layer 19 is provided on the upper surface of the base insulating layer 28. To be specific, in the terminal supporting portion 51, the conductive layer 19 is provided so as to be also formed on the upper surface of the thin portion 58.

Next, as shown in FIG. 10D, the cover insulating layer 29 is provided in the above-described pattern.

Next, as shown in FIG. 11E, the metal supporting layer 67 is trimmed. In this manner, the lower surface of the base insulating layer 28 (base insulating layer 28 including the thin portion 58) in the connecting portion 52 is exposed.

Then, as shown in FIG. 11F, the thin portion 58 is removed. To be specific, the thin portion 58 is removed by, for example, etching, or preferably wet etching or the like. In this manner, the lower surface of the inner-side portion of the piezoelectric-side terminal 40 is exposed from the base insulating layer 28.

Thereafter, as shown in FIG. 11G, the plating layer 47 is formed on the surfaces of the front-side terminals 26 (ref: FIG. 1), the rear-side terminals 27 (ref: FIG. 1), and the piezoelectric-side terminals 40.

As shown in FIG. 9, in order to bond the electrode 48 in the piezoelectric element 5 to the pad portion 33, the bonding material 42 is provided between the electrode 48 and the pad portion 33. To be specific, as referred in FIGS. 8A and 8B, the bonding material 42 is, in plane view, disposed in the electrode 48 so that the center of gravity G thereof is included in the through hole 56. Subsequently, the bonding material 42 flows.

Then, the bonding material 42, in side view, passes through the through hole 56 from the lower side of the through hole 56 in the pad portion 33 to swell upwardly and expands toward the outer side (both front and rear outer sides and both right and left outer sides) of the through hole 56 on the pad portion 33. That is, the bonding material 42 reaches a space at the upper side of the piezoelectric-side terminal 40 from a space at the lower side of the base insulating layer 28 and the piezoelectric-side terminal 40 via the through hole 56 in the piezoelectric-side terminal 40. That is, the bonding material 42 fills the through hole 56 and embeds, in side view, the connecting portion 52. That is, the bonding material 42 continuously embeds the upper and lower sides of the connecting portion 52 and the through hole 56.

In the third embodiment, the same function and effect as that of the first embodiment can be achieved. Furthermore, the terminal supporting portion 51 is formed into a generally annulus ring shape, so that the connecting portion 52 can be further more strongly supported, compared to the first embodiment (ref: FIGS. 3A and 3B) in which the terminal supporting portion 51 is formed into a generally semicircular arc shape in plane view. Thus, the bonding strength of the piezoelectric element 5 with the connecting portion 52 can be further improved.

In the suspension board with circuit 3, the entire inner peripheral surface 71 facing the through hole 56 in the pad portion 33 is divided only by the piezoelectric-side terminal 40 (conductive layer 19), so that when the bonding material 42 is provided in the pad portion 33 and the pad portion 33 is bonded to the piezoelectric element 5, a contact area of the bonding material 42 with the piezoelectric-side terminal 40 that divides the inner peripheral surface 71 facing the through hole 56 in the pad portion 33 can be sufficiently ensured. Thus, the electrical connection reliability of the piezoelectric element 5 with the piezoelectric-side terminal 40 in the pad portion 33 can be further improved.

### Modified Example of Third Embodiment

As shown by the phantom lines in FIGS. 9 and 11G, the terminal supporting portion 51 can also further include the supporting board 57.

The shape, arrangement, producing method, and function and effect of the supporting board 57 are the same as those in modified examples of the above-described first embodiment.

### Modified Example of Fourth Embodiment

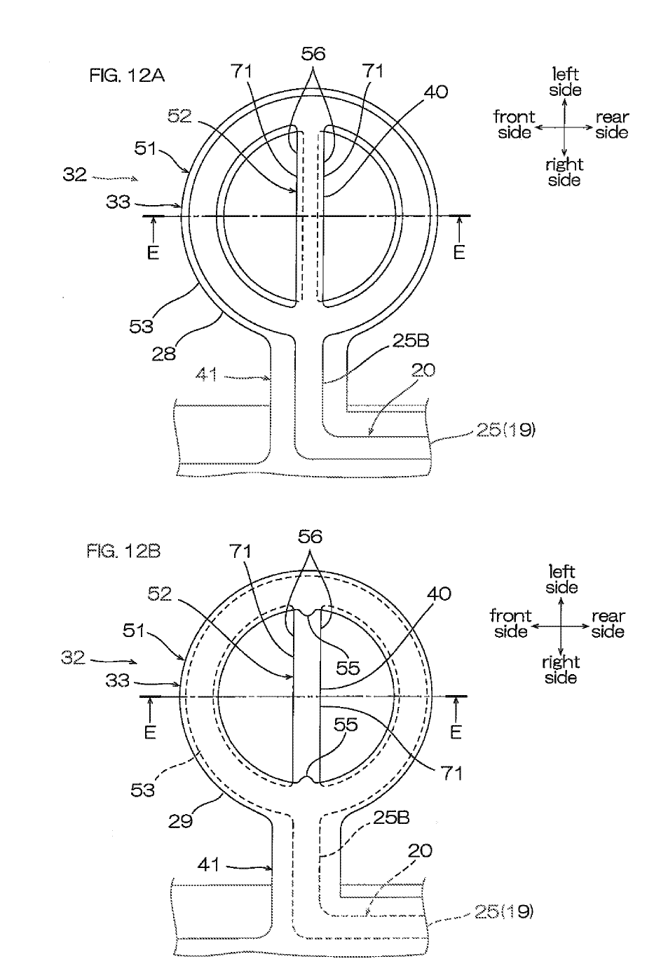

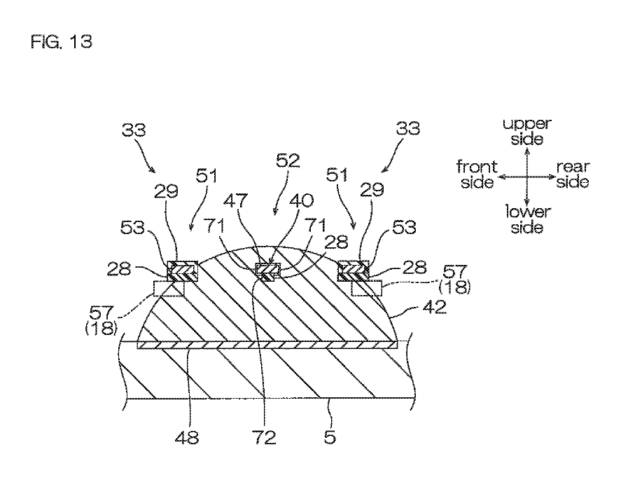

The suspension board with circuit 3 in the fourth embodiment is described with reference to FIGS. 12A, 12B, and 13. In the fourth embodiment, the same reference numerals are provided for members corresponding to each of those in the above-described first to third embodiments, and their detailed description is omitted.

In the above-described first embodiment, as shown in FIGS. 3A and 3B, the terminal supporting portion 51 is formed into a generally semicircular arc shape in plane view. Alternatively, in the third embodiment, as shown in FIGS. 12A and 12B, the terminal supporting portion 51 can be also formed into a generally annulus ring shape (generally ring shape) in plane view.

The connecting portion 52 passes through the center of the terminal supporting portion 51, extends along the radial direction of the terminal supporting portion 51, and connects the inner peripheral edge of the terminal supporting portion 51.

The through holes 56 are provided in both front and rear sides of the connecting portion 52. In the rear-side through hole 56, the rear end edge thereof is formed into a curved shape and the front end edge thereof is formed into a linear shape extending in the right-left direction. The front-side portion of the inner peripheral surface 71 facing the rear-side through hole 56 in the connecting portion 52 is divided only by the piezoelectric-side terminal 40.

As shown in FIG. 13, in order to bond the electrode 48 in the piezoelectric element 5 to the pad portion 33, the bonding material 42 is provided between the electrode 48 and the pad portion 33. To be specific, as referred in FIGS. 12A and 12B, the bonding material 42 is, in plane view, disposed in the electrode 48 so that the center of gravity G thereof is overlapped with the center in the right-left direction of the connecting portion 52. Subsequently, the bonding material 42 flows.

Then, as shown in FIG. 13, the bonding material 42, in side view, passes through a pair of through holes 56 from the lower side of a pair of through holes 56 in the pad portion 33 to swell upwardly and reaches the upper side of the connecting portion 52. To be specific, the bonding material 42 swells upwardly via a pair of through holes 56 so as to involve the connecting portion 52. That is, the bonding material 42 reaches a space at the upper side of the piezoelectric-side terminal 40 from a space at the lower side of the base insulating layer 28 and the piezoelectric-side terminal 40 via a pair of through holes 56. That is, the bonding material 42 embeds, in side view, the connecting portion 52 and fills each of a pair of through holes 56. That is, the boning material 42 is provided so as to continuously surround a space divided by the upper and lower sides of the connecting portion 52 and by a pair of through holes 56.

In the fourth embodiment, the same function and effect as that of the first embodiment can be achieved. Furthermore, the terminal supporting portion 51 is formed into a generally annulus ring shape, so that the connecting portion 52 can be further more strongly supported, compared to the first embodiment (ref: FIGS. 3A and 3B) in which the terminal supporting portion 51 is formed into a generally semicircular arc shape in plane view. Thus, the bonding strength of the piezoelectric element 5 with the connecting portion 52 can be further improved.

Furthermore, in the fourth embodiment, the bonding material 42 fills both of the two through holes 56, so that the connecting portion 52 can be more easily involved, compared to the third embodiment (ref: FIG. 9) in which the bonding material 42 fills one through hole 56. Therefore, in the fourth embodiment, the connecting portion 52 can be further more strongly supported. Thus, the bonding strength of the piezoelectric element 5 with the connecting portion 52 can be further improved.

### Modified Example of Fourth Embodiment

As shown by the phantom line in FIG. 13, the terminal supporting portion 51 can also further include the supporting board 57.

The shape, arrangement, producing method, and function and effect of the supporting board 57 are the same as those in modified examples of the above-described first embodiment.

### Fifth Embodiment

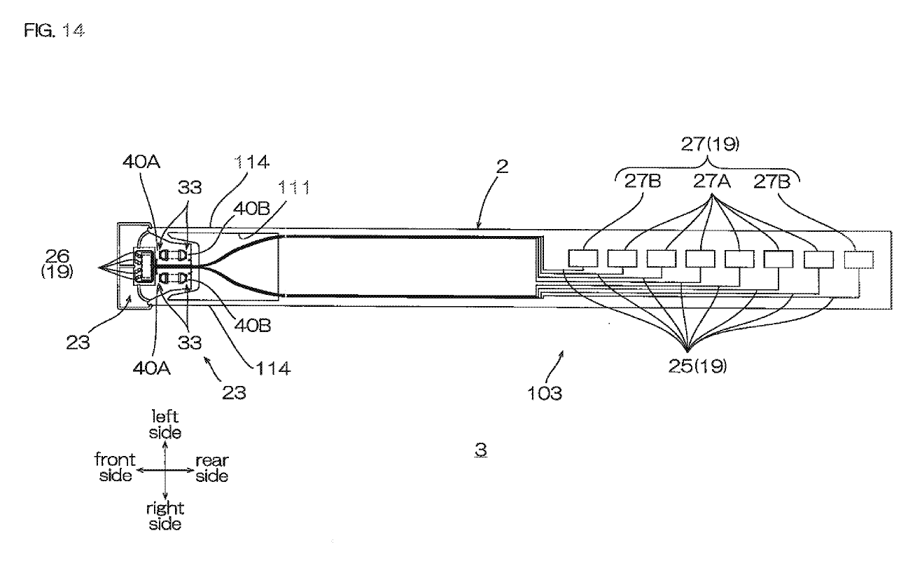

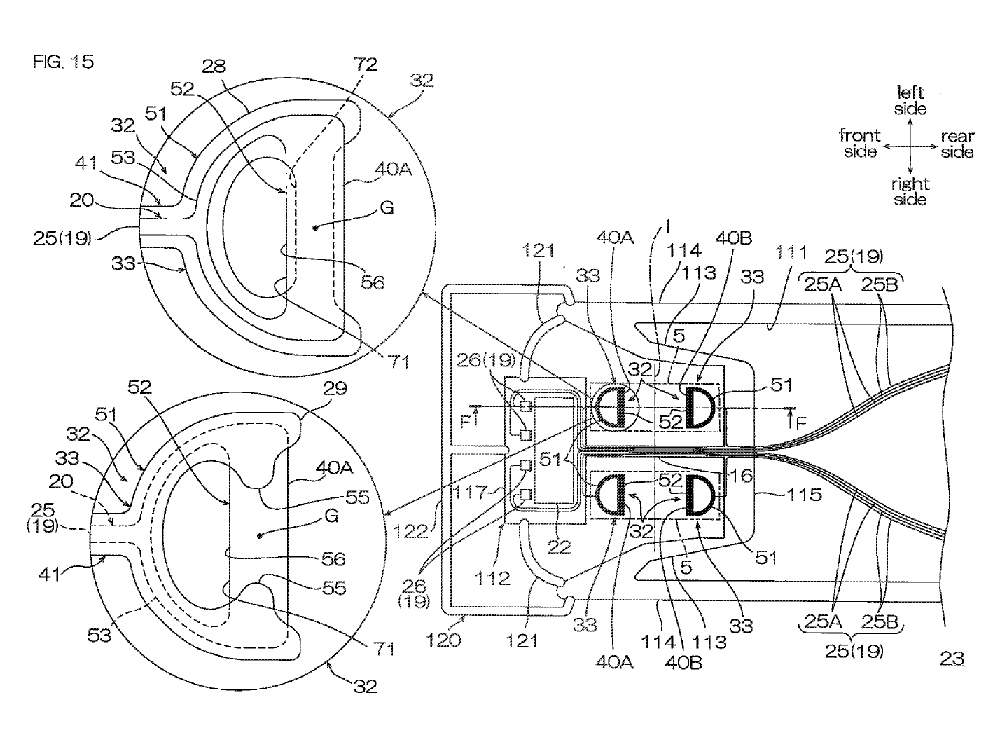

The assembly 1 in the fifth embodiment is described with reference to FIGS. 14 to 16. In the fifth embodiment, the same reference numerals are provided for members corresponding to each of those in the above-described first to fourth embodiments, and their detailed description is omitted.

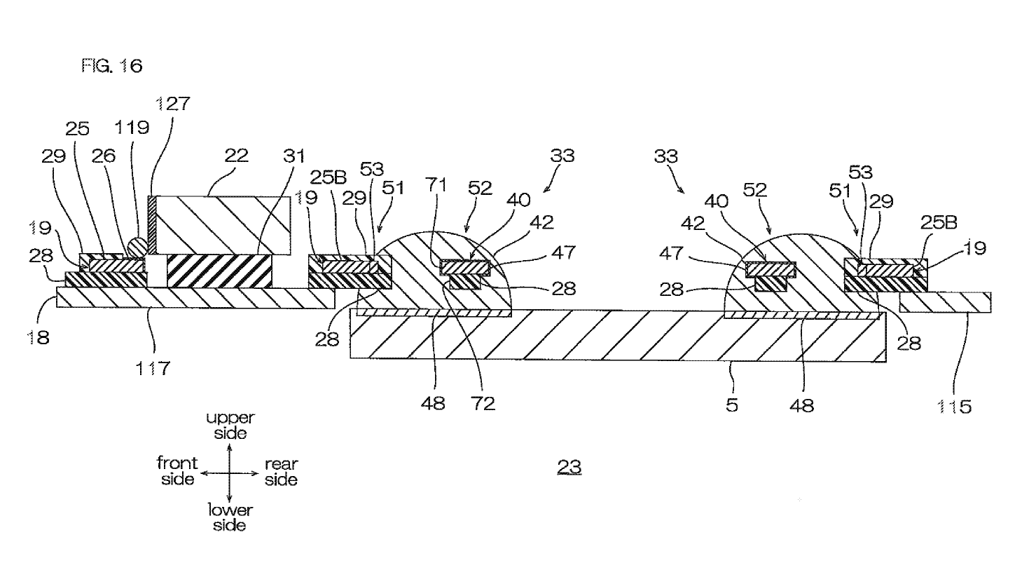

As referred in FIG. 2, in the assembly 1 in the first to fourth embodiments, the piezoelectric element 5 is fixed to the supporting plate 2 and then, the suspension board with circuit 3 that is fixed to the supporting plate 2 is electrically connected to the piezoelectric element 5. However, the connecting method is not limited to this and, as shown in FIG. 16, in the fifth embodiment, the piezoelectric element 5 can be also directly fixed to the suspension board with circuit 3.

In FIGS. 14 and 15, the assembly 1 is a head gimbal assembly (HGA) to be mounted on a hard disk (not shown) and includes the suspension board with circuit 3, a pair of piezoelectric elements 5 that are stretchably mounted on the suspension board with circuit 3, and the slider 22 that is mounted on the suspension board with circuit 3.

In the suspension board with circuit 3, the conductive layer 19 is supported by the metal supporting board 18.

The metal supporting board 18 is formed into a generally rectangular flat belt shape in plane view extending in the front-rear direction. The metal supporting board 18 integrally includes a main body portion 103 and the gimbal 23 that is formed at the front side of the main body portion 103.

The main body portion 103 is formed into a generally rectangular shape in plane view.

The gimbal 23 is formed so as to extend from the front end of the main body portion 103 toward the front side. In the gimbal 23, a board opening portion 111 in a generally rectangular shape in plane view that passes through the gimbal 23 in the thickness direction is formed. The gimbal 23 includes a pair of outrigger portions 114 that are divided at both right and left outer sides of the board opening portion 111 and a tongue portion 112 that is connected to the outrigger portions 114.

Each of the outrigger portions 114 is formed so as to extend in a linear shape from both end portions in the widthwise direction of the main body portion 103 toward the front side.

As shown in FIG. 15, the tongue portion 112 is provided at the inner side in the widthwise direction of the outrigger portions 114 and is connected to the outrigger portions 114 via first connecting portions 113 that extend from the front end portions of the outrigger portions 114 toward obliquely inner rear side in the widthwise direction. The tongue portion 112 is formed into a generally H-shape in plane view and integrally includes a base portion 115 in a generally rectangular shape in plane view extending long in the widthwise direction, a stage 117 in a generally rectangular shape in plane view extending long in the widthwise direction and disposed at the front side of the base portion 115 at spaced intervals thereto, and a central portion 116 in a generally rectangular shape in plane view that is long in the front-rear direction and connecting the center in the widthwise direction of the base portion 115 to that of the stage 117.

The stage 117 is provided so as to mount the slider 22 thereon and is connected to the outrigger portions 114 via a flexible second connecting portion 120. The second connecting portion 120 includes curved portions 121 that connect each of the front ends of a pair of outrigger portions 114 to both ends in the widthwise direction of the stage 117 in a curved shape and an E-shape portion 122 that connects each of the front ends of a pair of outrigger portions 114 to the front end of the stage 117. The curved portions 121 extend from the front ends of the outrigger portions 114 toward obliquely inner front side in the widthwise direction in a curved shape and reach both ends in the widthwise direction of the stage 117. The E-shape portion 122 is formed into a generally E-shape in plane view. To be specific, the E-shape portion 122 extends from the front ends of both of the outrigger portions 114 toward the front side; then bends inwardly in the widthwise direction; extends inwardly in the widthwise direction to be united; and then, bends rearwardly to finally reach the front end of the stage 117.

The central portion 116 is formed to be capable of curving in the widthwise direction with a narrow width.

As shown in FIG. 14, the conductive layer 19 includes the external side terminals 27, the head-side terminals 26, piezo front-side terminals 40A, piezo rear-side terminals 40B, and the wires 25.

The external side terminals 27 are provided in the rear end portion of the main body portion 103. A plurality (eight pieces) thereof are disposed at spaced intervals to each other in the front-rear direction. The external side terminals 27 include a plurality (six pieces) of external side terminals 27A and a plurality (two pieces) of power supply-side terminals 27B.

As shown in FIG. 15, the head-side terminals 26 are provided in the front end portion of the stage 117. A plurality (four pieces) thereof are disposed at spaced intervals to each other in the widthwise direction.

The piezo front-side terminals 40A have the same structure as that of the piezoelectric-side terminals 40 in the above-described first embodiment. To be specific, each of the piezo front-side terminals 40A is provided in the pad portion 33 in each of the connecting arms 32. The joint portion 41 in the connecting arm 32 is formed so as to protrude from the rear end edge of both right and left outer side portions of the stage 117 rearwardly to reach the center in the right-left direction of the terminal supporting portion 51. A plurality (two pieces) of piezo front-side terminals 40A are disposed at spaced intervals to each other in the right-left direction.

The piezo rear-side terminals 40B are configured to be line symmetrical with respect to the piezo front-side terminals 40A based on a phantom line I passing through the center in the front-rear direction and along the right-left direction of the central portion 116. The connecting arms 32 corresponding to the piezo rear-side terminals 40B are formed so as to protrude from the rear end edges of both right and left outer-side portions of the base portion 115 forwardly to reach the terminal supporting portions 51.

As shown in FIG. 14, the wires 25 are continuous to the external side terminals 27, the head-side terminals 26, the piezo front-side terminals 40A, and the piezo rear-side terminals 40B and electrically connect these to each other. A plurality (ten pieces) of wires 25 are, in the main body portion 103, formed at spaced intervals to each other in the right-left direction. To be specific, the wires 25 are disposed so as to extend from the external side terminals 27 toward the front side in the rear end portion of the main body portion 103; bend in a branched shape into two bunches toward both right and left sides in the center in the right-left direction of the main body portion 103; then, bend toward the front side in both right and left end portions; and extend along both outer end edges in the widthwise direction toward the front end portion of the main body portion 103. As shown in FIG. 15, the wires 25 are disposed so as to pass through the board opening portion 111 in the gimbal 23 and reach the middle in the front-rear direction of the base portion 115 in a bundled shape. The wires 25, in the base portion 115, branch into three ways, to be specific, into both right and left sides and the front side. Of these, a plurality (eight pieces) of wires 25 in a bundled shape toward the front side are formed so as to extend toward the front side along the central portion 116; then, bend in a branched shape into two bunches toward both right and left sides in the rear end portion of the stage 117; thereafter, extend along the peripheral edge of the stage 117; and finally, be folded back to reach the terminal supporting portions 51 of the head-side terminals 26 and the piezo front-side terminals 40A. Meanwhile, one wire 25 that branches into both outer sides in the base portion 115 is formed so as to bend toward the front side in both right and left outer end portions of the base portion 115 to reach the terminal supporting portions 51 of the piezo rear-side terminals 40B.

As shown in FIG. 16, the suspension board with circuit 3 includes the metal supporting board 18, the base insulating layer 28 that is formed on the metal supporting board 18, the conductive layer 19 that is formed on the base insulating layer 28, and the cover insulating layer 29 that is formed on the base insulating layer 28 so as to cover the conductive layer 19.

As shown in FIG. 1, the metal supporting board 18 is formed into a shape corresponding to the outer shape of the suspension board with circuit 3.

As referred in FIGS. 1 and 2, the base insulating layer 28 is formed over the main body portion 103 and the gimbal 23 and is, as shown in FIG. 3, formed corresponding to a portion in which the conductive layer 19 is formed. To be specific, the base insulating layer 28 is, in the main body portion 103, formed at the inside of the board opening portion 111 in the gimbal 23 and on the central portion 116 along the wires 25, while being formed on the metal supporting board 18. Furthermore, the base insulating layer 28 is formed into a pattern corresponding to a pair of connecting arms 32.

As described above, the conductive layer 19 is formed as a conductive pattern including the external side terminals 27 (FIG. 1), the head-side terminals 26, the piezo front-side terminals 40A, the piezo rear-side terminals 40B, and the wires 25.

As shown in FIG. 15, the slider 22 is formed into a generally rectangular shape in plane view that is smaller than the stage 117 with the lengthwise direction thereof along the right-left direction and is mounted on the center in the right-left and front-rear directions of the stage 117. As shown by the dashed line in FIG. 15, and in FIG. 16, the central portion of the slider 22 adheres to the central portion of the stage 117 via the adhesive layer 31 made of a known adhesive.

The magnetic head 127 is mounted on the entire front end surface of the slider 22 and is formed into a generally box shape extending in the up-down direction. The magnetic head 127 is formed along a plurality of head-side terminals 26 and, to be specific, as shown in FIG. 16, is formed at the rear side of the head-side terminals 26 at minute spaced intervals thereto. In this manner, the magnetic head 127 is electrically connected to the head-side terminals 26 with a solder ball 119 or the like.

In order to produce the assembly 1, a pair of piezoelectric elements 5 are disposed at the lower side of the suspension board with circuit 3 so that the electrodes 48 (ref: FIG. 16) that are provided in the front end portion and the rear end portion of the upper surface of each of the piezoelectric elements 5 are disposed in opposed relation to the piezo front-side terminals 40A and the piezo rear-side terminals 40B in the thickness direction.

Subsequently, the bonding material 42 is provided in the electrode 48 so that the center of gravity G of the bonding material 42 is overlapped with the center in the right-left direction of the connecting portion 52, and subsequently, the bonding material 42 flows. Then, the connecting portion 52 is embedded in the bonding material 42. Along with this, the bonding material 42 fills the through hole 56.

In this manner, the piezoelectric elements 5 are electrically connected to the piezoelectric-side terminals 40 in the suspension board with circuit 3.

Separately, the gimbal 23 is mounted on the suspension board with circuit 3 and the magnetic head 127 is electrically connected to the head-side terminals 26.

Also, a read/write board (not shown), a power supply, and the external side terminals 27 are electrically connected to each other.

In the fifth embodiment, the same function and effect as that of the above-described first embodiment can be achieved. Furthermore, the piezoelectric element 5 is directly fixed to the suspension board with circuit 3, so that the slider 22 that is fixed to the suspension board with circuit 3 can be efficiently and surely vibrated.

In the above-described first to fifth embodiments, an example of the electronic element includes the piezoelectric element 5, but the electronic element is not limited to this. An example thereof can also include a luminous element. In such a case, a magnetic head in the suspension board with circuit 3 magnetically records in a hard disk drive by an optical assist method (optical assist magnetic recording method or thermal assist recording method).

In the above-described first to fifth embodiments, examples of the suspension board with circuit of the present invention include an embodiment in which the suspension board with circuit 3 is mounted with the piezoelectric element 5 and an embodiment in which the suspension board with circuit 3 is not yet mounted with the piezoelectric element 5.

While the illustrative embodiments of the present invention are provided in the above description, such is for illustrative purpose only and it is not to be construed as limiting the scope of the present invention. Modification and variation of the present invention that will be obvious to those skilled in the art is to be covered by the following claims.

What is claimed is:

1. A suspension board with circuit comprising:
a pad portion configured to be bonded to an electronic element, wherein
the pad portion includes a conductive layer;
in the pad portion, a through hole passing through the pad portion with its periphery closed by the pad portion is formed; and
at least a part of an inner peripheral surface facing the through hole in the pad portion is divided only by the conductive layer.

2. The suspension board with circuit according to claim 1, wherein
the pad portion further includes an insulating layer that is disposed at one surface in a penetrating direction of the through hole in the conductive layer and
the part in the pad portion is disposed at the inner side of the through hole with respect to the inner peripheral surface facing the through hole in the insulating layer.

3. The suspension board with circuit according to claim 1, wherein
both surfaces in the penetrating direction of the through hole in the conductive layer that divides the part in the pad portion are exposed.

4. The suspension board with circuit according to claim 1, wherein
the entire inner peripheral surface in the pad portion is divided only by the conductive layer.

5. A suspension board with circuit comprising:
an electronic element,
a connecting portion electrically connecting to the electronic element, and
a bonding material bonding the electronic element to the connecting portion, wherein
the bonding material embeds the connecting portion.

6. The suspension board with circuit according to claim 5, wherein
the bonding material is provided so as to continuously surround one side in a thickness direction of the connecting portion, an opposite side in the thickness direction of the connecting portion, and a lateral side continuous to the one side and the opposite side in the thickness direction of the connecting portion.

7. The suspension board with circuit according to claim 5 further comprising:
an insulating layer and
a conductive layer included at one side in a thickness direction of the insulating layer and including a terminal, wherein
the connecting portion includes the insulating layer and the terminal and
the bonding material is provided so as to continuously surround one side in the thickness direction of the insulating layer and the terminal in the connecting portion, an opposite side in the thickness direction of the insulating layer and the terminal in the connecting portion, and a lateral side continuous to the one side and the opposite side in the thickness direction of the insulating layer and the terminal in the connecting portion.

8. The suspension board with circuit according to claim 5 further comprising:
a conductive layer including a terminal, wherein
the connecting portion includes the terminal and
the bonding material is provided so as to continuously surround one side in the thickness direction of the terminal in the connecting portion, an opposite side in the thickness direction of the terminal in the connecting portion, and a lateral side continuous to the one side and the opposite side in the thickness direction of the terminal in the connecting portion.
